(19) United States
(12) Patent Application Publication
(10) Pub. No.: US 2025/0137723 A1
(43) Pub. Date: May 1, 2025

(54) CHAMBER BODIES HAVING MACHINED WALLS, CHAMBER ARRANGEMENTS AND SEMICONDUCTOR PROCESSING SYSTEMS HAVING CHAMBER BODIES WITH MACHINED WALLS, AND METHODS OF MAKING CHAMBER BODIES

(71) Applicant: ASM IP Holding B.V., Almer (NL)

(72) Inventors: Felix Rabinovich, Scottsdale, AZ (US); Terry Parde, Chandler, AZ (US); Gary Urban Keppers, Morgan Hill, CA (US); Amin Azimi, Phoenix (AZ); Alicia Almeda, Chandler, AZ (US); Fauhmee Oudeif, Phoenix, AZ (US); Amir Kajbafvala, Chandler, AZ (US); Arun Murali, Tempe, AZ (US); Frederick Aryeetey, Phoenix, AZ (US); Alexandros Demos, Scottsdale, AZ (US); Nayna Khosla, Tempe, AZ (US); Caleb Miskin, Mesa, AZ (US); Hichem M'Saad, Paradise Valley, AZ (US); Shivaji Peddeti, Phoenix, AZ (US); Steven Reiter, Phoenix, AZ (US)

(21) Appl. No.: 18/928,413

(22) Filed: Oct. 28, 2024

Related U.S. Application Data
(60) Provisional application No. 63/546,606, filed on Oct. 31, 2023.
(60) Provisional application No. 63/546,608, filed on Oct. 31, 2023.
(60) Provisional application No. 63/546,611, filed on Oct. 31, 2023.

(51) Int. Cl. F27B 17/00; B28B 11/02; B28D 1/02; B28D 1/14; B28D 1/18

(52) U.S. Cl. CPC F27B 17/0025; B28B 11/02; B28D 1/02; B28D 1/14; B28D 1/18

(57) ABSTRACT

A chamber body includes a ceramic weldment having a lower wall, a sidewall, and an upper wall. The sidewall is coupled to the lower wall by a sidewall-to-lower wall weld and the upper wall is coupled to the sidewall by a sidewall-to-upper wall weld. The upper wall has an upper wall plate portion and an upper wall rib portion extending therefrom formed from a singular quartz workpiece using a subtractive manufacturing technique, the upper wall further having a unwelded ribbed region overlying the lower wall. Chamber arrangements, semiconductor processing systems and related methods of making chamber bodies and depositing material layers onto substrates supported within chamber bodies are also described.

### CROSS-REFERENCE TO RELATED APPLICATIONS

This application claims priority to and the benefits of U.S. Provisional Patent Application No. 63/546,606, U.S. Provisional Patent Application No., 63/546,608, and U.S. Provisional Patent Application 63/546,611, each filed on Oct. 31, 2023, the contents each of which are also incorporated herein by reference in their entirety.

### FIELD OF INVENTION

The present disclosure generally relates to chamber bodies, and more particularly to methods of making chamber bodies from ceramic materials such as quartz.

### BACKGROUND OF THE DISCLOSURE

Quartz articles, such as chambers employed to deposit material layers in semiconductor processing system, are commonly formed using welding techniques. For example, cold wall chambers used for material layer deposition using chemical vapor deposition techniques generally commonly include walls bounding a process space with structural members joined to the walls with welds. The structural elements are typically welded to the walls, such as using a hydrogen gas welding technique, enabling the process space contained within the chamber walls to be maintained at relative to low pressure relative to the external environment during material layer deposition onto substrates supported within the chamber.

One challenge to employing welded quartz articles is a tendency of the welding process to introduce artifacts into the chamber weldment during fabrication. For example, gas bubbles and/or inclusions formed non-native materials may infiltrate the ceramic weldment structure during welding, potentially altering the optical properties of the ceramic weldments and/or the strength of the ceramic weldment. The localized nature of the heating employed during the welding process and subsequent cooling may impart residual stress into the ceramic weldment structure, potentially limiting strength of the ceramic weldment and increasing risk that the ceramic weldment fracture during subsequent handling and/or fabrication processes. The heat employed during the welding process may distort shape of the ceramic weldment during welding in a way that departs dimensionally from the dimensions of the intended weldment, potentially altering properties of the resulting weldment.

Various countermeasures exist to limit the introduction of artifact into weldments and/or remove artifacts from weldments subsequent to the welding process. For example, welding may be accomplished in environmentally controlled workspaces to limit contaminant introduction. The members being welded may further be cleaned prior to welding, also limiting risk that contaminant be introduced into the ceramic weldment during welding. Residual stress imparted by the welding process may be removed (at least in part) by annealing the ceramic weldment subsequent to the welding process, the uniform heating and subsequent controlled cooling limiting stress that could otherwise limit strength of the ceramic weldment. And heating of the articles being joined may be carefully controlled during the heating process to limit distortion of the shapes defined by resulting weldment, the ceramic weldment thereby more likely to satisfy the dimensional requirements of the application for which the ceramic weldment is to be employed. While generally satisfactory for its intended purpose, such techniques can add cost and complexity to the fabrication of quartz articles. For example, weldments formed from multiple welds may require multiple anneal operations due to the need to remove residual stress introduced during a prior welding operation prior to undergoing a subsequent welding operation, prolonging the fabrication process.

Such chambers and methods of making chambers using welding techniques have generally been considered suitable for their intended purpose. However, there remains a need in the art for improved chamber bodies, chamber arrangements and semiconductor processing systems including chamber bodies, and related methods of making chamber bodies. The present disclosure provides a solution to this need.

### SUMMARY OF THE DISCLOSURE

A chamber body is provided. The chamber body incudes a ceramic weldment having a lower wall, a sidewall, and an upper wall. The sidewall is coupled to the lower wall by a sidewall-to-lower wall weld and the upper wall is coupled to the sidewall by a sidewall-to-upper wall weld. The upper wall has an upper wall plate portion and an upper wall rib portion extending therefrom formed from a singular quartz workpiece using a subtractive manufacturing technique, the upper wall further having a unwelded ribbed region overlying the lower wall.

In addition to one or more of the features described above, or as an alternative, further examples of the chamber body may include that the ceramic weldment forming the chamber body also includes an inject end flange coupled to the upper wall by an inject end flange-to-upper wall weld and an exhaust end flange coupled to the upper wall by an exhaust end flange-to-upper wall weld. The ceramic weldment may consist essentially of quartz.

In addition to one or more of the features described above, or as an alternative, further examples of the chamber body may include that the sidewall is a first sidewall the chamber body has a second sidewall extending in parallel with the first sidewall. The second sidewall may be coupled to the lower wall by a second sidewall-to-lower wall weld. The second sidewall may be coupled to the upper wall by the second sidewall-to-upper wall weld.

In addition to one or more of the features described above, or as an alternative, further examples of the chamber body may include that the lower wall has a lower wall rib portion extending in a direction opposite the sidewall and the upper wall of the ceramic weldment. The ceramic weldment may further have two or more first side rib segments coupled to the upper wall rib portions by two or more first side rib segment-to-upper wall welds, the two or more first side rib segments further coupled to the lower wall rib portion by a plurality of first side rib segment-to-lower wall welds; and two or more second side rib segments coupled to the upper wall rib portion by two or more second side rib segment-to-upper wall welds, the two or more second side rib segments coupled to the lower wall rib portion by two or more second side rib segment-to-lower wall welds.

In addition to one or more of the features described above, or as an alternative, further examples of the chamber body may include that the lower wall has a lower wall plate portion separating the lower wall rib portion from the first sidewall and the second sidewall. The lower wall plate portion and the lower wall rib portion may be formed from another singular quartz workpiece using the subtractive manufacturing technique.

In addition to one or more of the features described above, or as an alternative, further examples of the chamber body may include that the lower wall defines a passthrough. A tubulation body may be registered to the passthrough and coupled to the lower wall at the passthrough by a tubulation body-to-lower wall weld.

In addition to one or more of the features described above, or as an alternative, further examples of the chamber body may include that the upper wall has an upper wall unwelded ribbed region defined using the subtractive manufacturing technique and extending about the passthrough. The upper wall unwelded ribbed region may have a diameter greater than 300 millimeters extending about (e.g., concentrically) the passthrough. The upper wall unwelded ribbed region may extend about a rotation axis extending through the tubulation body and the passthrough.

In addition to one or more of the features described above, or as an alternative, further examples of the chamber body may include that the lower wall may have a lower wall unwelded ribbed region extending about the passthrough. The lower wall unwelded ribbed region may be bounded by a first sidewall-to-lower wall weld. The lower wall unwelded ribbed region may bounded by a second sidewall-to-lower wall weld laterally opposite the first sidewall-to-lower wall weld.

In addition to one or more of the features described above, or as an alternative, further examples of the chamber body may include that the lower wall unwelded ribbed region is bounded by an inject end flange-to-lower wall weld and an exhaust end flange-to-lower wall weld that is longitudinally opposite the inject end flange-to-lower wall weld.

A chamber arrangement is provided. The chamber arrangement includes a chamber body as described above, a substrate support, a support member, and a shaft member. The lower wall of the chamber body may define a passthrough include a passthrough. The passthrough may be registered to the passthrough and coupled to the lower wall by a tubulation body-to-lower wall weld. The substrate support may be arranged within an interior of the chamber body and supported for rotation about a rotation axis extending through the passthrough. The support member is arranged along the rotation axis and fixed in rotation relative to the substrate support. The shaft member is arranged along the rotation axis, fixed in rotation relative to the support member, and extends through the passthrough and the tubulation body to operably couple a lift and rotate module to the substrate support.

In addition to one or more of the features described above, or as an alternative, further examples of the chamber arrangement may include that the lower wall has an upper wall unwelded ribbed region extending about the passthrough an upper heater element array with a plurality of upper heater elements supported above the upper wall of the chamber body and overlying the substrate support. The upper wall unwelded ribbed region may optically couples the plurality of upper heater elements to the interior of the chamber body.

In addition to one or more of the features described above, or as an alternative, further examples of the chamber arrangement may include a pyrometer supported above the chamber body and arranged along an optical axis intersecting the substrate support. The upper wall unwelded ribbed region optically coupled the pyrometer to the interior of the chamber body.

A semiconductor processing system is provided. The semiconductor processing system includes a chamber body as described above, a substrate support arranged within an interior of the chamber body and configured to support a substrate during deposition of a material layer onto an upper surface of the substrate, a precursor source including a silicon-containing material layer precursor coupled to an injection end of the chamber body, and an exhaust source including a vacuum pump coupled to an exhaust end of the chamber body and therethrough to the precursor source.

A method of making a weldment for a chamber body is provided. The method includes forming an upper wall having an upper wall plate portion and an upper wall rib portion extending from the upper wall plate portion from a first singular quartz workpiece using a subtractive manufacturing technique, forming a lower wall having a lower wall plate portion and a lower wall rib portion extending from the lower wall plate portion from a second singular quartz workpiece using the subtractive manufacturing technique, and coupling a first sidewall to a lower wall with a first sidewall-to-lower wall weld. The method also includes coupling a second sidewall to the lower wall with a second sidewall-to-lower wall weld, coupling the upper wall plate portion of the upper wall to the first sidewall with a first sidewall-to-upper wall weld, and coupling the upper wall plate portion of the upper wall to the second sidewall with a second sidewall-to-upper wall weld, whereby the upper wall defines a unwelded ribbed region overlying the lower wall and separated from the lower wall by the first side wall and the second sidewall.

In addition to one or more of the features described above, or as an alternative, further examples of the method may include registering an inject end flange to an inject lateral edge of the lower wall plate portion of the lower wall and coupling the inject end flange to the lower wall with an inject end flange-to-lower wall weld, and registering an inject lateral edge of the upper wall to the inject end flange and coupling the inject end flange to the upper wall with an inject end flange-to-upper wall weld.

In addition to one or more of the features described above, or as an alternative, further examples of the method may include registering an exhaust end flange to an exhaust lateral edge of the lower wall plate portion of the lower wall and coupling the exhaust end flange to the lower wall with an exhaust end flange-to-lower wall weld, and registering an exhaust lateral edge of the upper wall to the exhaust end flange and coupling the exhaust end flange to the upper wall with an exhaust end flange-to-upper wall weld.

In addition to one or more of the features described above, or as an alternative, further examples of the method may include defining a passthrough extending through the lower wall of the chamber body, and coupling a tubulation body to the lower wall with a tubulation body-lower wall weld, whereby the upper wall unwelded ribbed region overlays and extends about the passthrough.

In addition to one or more of the features described above, or as an alternative, further examples of the method may include registering a plurality of first side rib segments to the upper wall rib portion of the upper wall and the lower wall rib portion of the lower wall, coupling the plurality of first side rib segments to the to upper wall rib portion with a plurality of first side rib-to-upper wall welds, and coupling the plurality of first side rib segments to the lower wall rib portion with a plurality of first side rib-to-lower wall welds, whereby one or more of the plurality of first side rib segments floats relative to the first sidewall.

In addition to one or more of the features described above, or as an alternative, further examples may include annealing the ceramic weldment, registering a plurality of second side rib segments to the upper wall rib portion of the upper wall and the lower wall rib portion of the lower wall, coupling the plurality of second side rib segments the to the upper wall rib portion with a plurality of second side rib-to-upper wall welds, and coupling the plurality of second side rib segments to the lower wall rib portion with a plurality of second side rib-to-lower wall welds. One or more of the plurality of second side rib segments may float relative to the second sidewall.

In addition to one or more of the features described above, or as an alternative, the subtractive manufacturing technique may include one or more of milling, core-drilling, and sawing to define at least one of the upper wall rib portion of the upper wall and the lower wall rib portion of the lower wall of the weldment.

A semiconductor processing system may include a chamber arrangement including a chamber body having a ceramic weldment as described above formed using the method as described above.

A material layer deposition method is provided. The method includes, at a chamber body as described above, seating a substrate within the chamber body, heating the substrate using an upper heater element array, exposing the substrate to a silicon-containing material precursor, and depositing a silicon-containing material layer onto the substrate using the silicon-containing material precursor. Heating of the substrate may be throttled using the upper heater element array during deposition of the silicon-containing material layer using a pyrometer. It is contemplated that the upper heater be optically coupled to the substrate by the unwelded ribbed region of the upper wall, the pyrometer be optically coupled to the substrate by the unwelded ribbed region of the upper wall, and that the unwelded ribbed region of the upper wall limits cross-substrate variation within the material relative to a chamber body having an upper wall welded ribbed region optically coupling an upper heater element array and/or a pyrometer to the substrate.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a chamber arrangement with a chamber body in accordance with the present disclosure, showing upper and lower walls of the chamber body formed using a subtractive manufacturing technique;

FIG. 2 is a cross-sectional side view of the chamber body of FIG. 1 according to an example of the present disclosure, showing an upper heater element array supported above an upper wall of the chamber body formed using a subtractive manufacturing technique;

FIG. 3 is a top plan view of a weldment forming the chamber body of FIG. 1 according to an example of the disclosure, showing an upper wall plate portion and an upper wall rib portion formed from a singular quartz workpiece using a subtractive manufacturing technique;

FIG. 4 is a bottom plan view of the ceramic weldment forming the chamber body of FIG. 1 according to an example of the disclosure, showing a lower wall plate portion and a lower wall rib portion of the lower wall formed from another singular quartz workpiece using the subtractive manufacturing technique;

FIG. 5 is a first side elevation view of the ceramic weldment forming the chamber body of FIG. 1 according to an example of the disclosure, showing first side rib segments and end flanges coupled to the ceramic weldment using first side rib segment welds and end flange welds;

FIG. 6 is a second side elevation view of the ceramic weldment forming the chamber body of FIG. 1 according to an example of the disclosure, showing second side ribs and end flanges coupled to the ceramic weldment using second side rib segment welds and end flange welds;

FIGS. 7-11 are schematic views of a method of making a weldment to form a chamber body using an upper wall and an lower wall formed using a subtractive manufacturing technique, showing a weldment being formed by coupling sidewalls and end flanges to the lower wall of the chamber body using welds and the upper wall and side rib segments thereafter being coupled to the ceramic weldment using welds;

FIG. 12 is graph of cross-substrate material layer thickness on a substrate deposited within the chamber body of FIG. 1 and a chamber body having an all-welded construction, showing reduction in cross-substrate material layer thickness in the chamber body having the upper wall and the lower wall formed using the subtractive manufacturing technique;

FIGS. 13-15 are a process flow diagram of a method of making a chamber body for a chamber arrangement included in a semiconductor processing system, showing operations of the method according to an illustrative and non-limiting example of the method; and

FIG. 16 is a process flow diagram of a method of depositing a material layer onto a substrate supported within a chamber having an upper wall formed using a subtractive manufacturing technique, showing operations of the method according to an non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

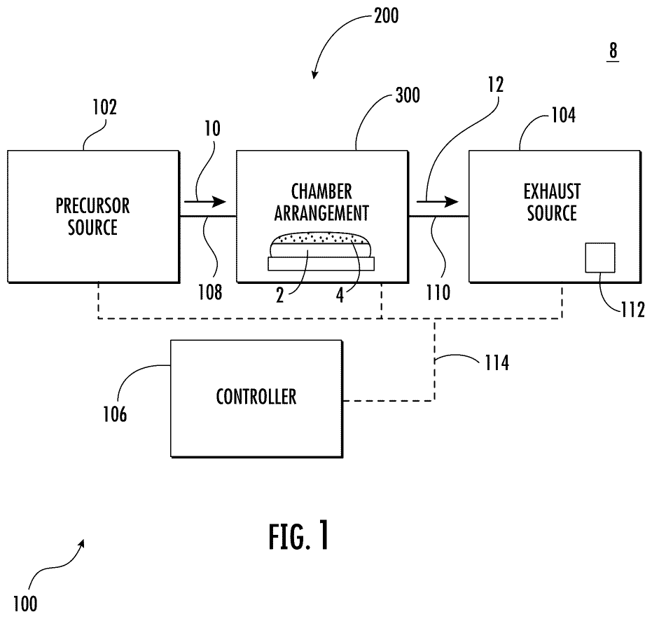

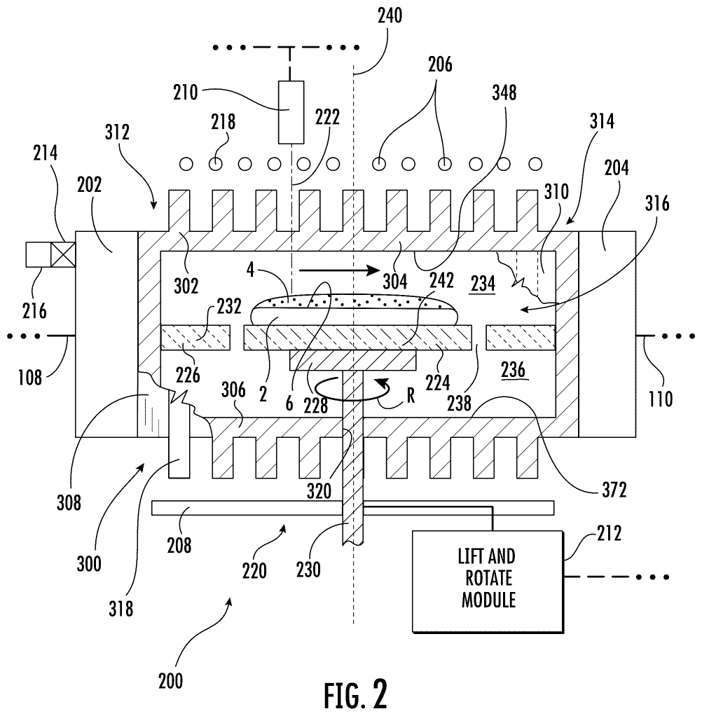

Reference will now be made to the drawings wherein like reference numerals identify similar structural features or aspects of the subject disclosure. For purposes of explanation and illustration, and not limitation, a partial view of an example of a semiconductor processing system including a chamber arrangement with a chamber body in accordance with the present disclosure is shown in FIG. 1 and is designated generally by reference character 100. Other examples of chamber bodies, chamber arrangements and semiconductor processing systems including chamber bodies in accordance with the present disclosure, and related methods a making chamber bodies and depositing material layers onto substrates supported in chamber bodies in accordance with the present disclosure, or aspects thereof, are provided in FIGS. 2-16, as will be described. The systems and methods of the present disclosure may be used to make and use chamber bodies employed to deposit material layers onto substrates, such as silicon-containing epitaxial material layers deposited using chemical vapor deposition techniques in chamber arrangements having crossflow architectures, thought the present disclosure is not limited to any particular deposition technique or chamber architecture in general.

Referring to FIG. 1, the semiconductor processing system 100 is shown. The semiconductor processing system 100 includes a precursor source 102, a chamber arrangement 200 including a chamber body 300, an exhaust source 104, and a controller 106. The precursor source 102 is connected to the chamber arrangement 200 by a precursor supply conduit 108 and is configured to provide a flow of a material layer precursor 10 to the chamber arrangement 200. The chamber arrangement 200 is connected to the exhaust source 104 and is configured to expose a substrate 2 supported within the chamber arrangement 200 to the material layer precursor 10 under environmental conditions (e.g., temperature and pressure) selected to cause a material layer 4 to deposit onto an upper surface 6 of the substrate 2. The exhaust source 104 is connected to the chamber arrangement 200 by an exhaust conduit 110, is fluidly coupled to an external environment 8 outside of the semiconductor processing system 100 (e.g., through a vacuum pump 112 and/or an abatement device such as a scrubber), and is configured to communicate a flow of residual material layer precursor and/or reaction products 12 to the external environment 8.

It is contemplated that the controller 106 may be operably connected to one or more of the precursor source 102, the chamber arrangement 200, and the exhaust source 104 to control deposition of the material layer 4 onto the substrate 2. In this respect the controller 106 may be connected to one or more of the precursor source 102, the chamber arrangement 200, and the exhaust source 104 by a wired or wireless link 114 to control temperature of the substrate 2 and/or pressure within the chamber body 300. Temperature of the substrate 2 may be controlled, for example, using heater elements and/or temperature sensors included in the chamber arrangement 200 and operatively associated with the controller 106. Pressure within the chamber body 300 may be controlled using the vacuum pump included in the exhaust source 104.

In certain examples, the material layer precursor 10 may include one or more silicon-containing material layer precursor. Examples of suitable silicon-containing material layer precursor include non-halogenated silicon-containing material layer precursors, such as silane (SiH₄) and disilane (Si₂H₆), and halogenated silicon-containing material layer precursors, such as dichlorosilane (H₂SiCl₂) and trichlorosilane (HCl₃Si). In accordance with certain examples, the material layer precursor 10 may include an alloying constituent, such as germanium-containing material layer precursor such as germane (GeH₄), a gallium-containing material layer precursor such as triethylgallium Ga(C₂H₅)₃, or an indium-containing material layer precursor such as trimethylindium ((CH₃)₃In). It is contemplated that, in certain examples, the material layer precursor 10 may include one or more dopant-containing material layer precursor. Examples of suitable dopant-containing material layer precursors include p-type dopants like boron (B) and arsenic (As) as well as n-type dopants such as phosphorous (P) and antimony (Sb). It is contemplated that, in accordance with certain examples, the material layer precursor 10 may be co-flowed with a diluent/carrier gas such as hydrogen (H₂) gas or nitrogen (N₂) gas and/or with an etchant, such as hydrochloric (HCl) acid or chlorine (Cl₂) gas.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the chamber arrangement 200 is shown. In the illustrated example the chamber arrangement 200 includes the chamber body 300, an injection flange 202, and an exhaust flange 204. In the illustrated example the chamber arrangement 200 also includes an upper heater element array 206, a lower heater element array 208, a pyrometer 210, and a lift and rotate module 212. Although shown and described herein as having certain elements and a specific architecture, e.g., a single substrate crossflow architecture, it is to be understood and appreciated that semiconductor processing systems having chamber arrangement including other elements and/or excluding elements shows and described herein, as well as having different architectures, may also benefit from the present disclosure.

The chamber body 300 is formed from a ceramic material 302 and has an upper wall 304, a lower wall 306, a first sidewall 308, and a second sidewall 310. The upper wall 304 extends longitudinally between an injection end 312 and a longitudinally opposite exhaust end 314. The lower wall 306 is spaced apart from the upper wall 304 by an interior 316 of the chamber body 300, and may be substantially parallel to the upper wall 304 of the chamber body 300. The first sidewall 308 couples the lower wall 306 of the chamber body 300 to the upper wall 304 of the chamber body 300, longitudinally spans the injection end 312 and the exhaust end 314 of the chamber body 300, and may be substantially orthogonal relative to either r (or both) the lower wall 306 and the upper wall 304 of the chamber body 300. The second sidewall 310 is similar to the first sidewall 308, and is additional laterally separated from the first sidewall 308 by a lateral width of the interior 316 of the chamber body 300. It is contemplated that the chamber body 300 may have a plurality of external ribs 318 extending laterally about the exterior surfaces of the upper wall 304, the lower wall 306, the first sidewall 308, and the second sidewall 310, and the plurality of external ribs 318 be longitudinally spaced apart from one another between the injection end 312 and the exhaust end 314 of the chamber body 300. It also contemplated that the injection flange 202 abut the injection end 312 of the chamber body 300 and couple the precursor supply conduit 108 to the chamber body 300, that the exhaust flange 204 abut the exhaust end 314 of the chamber body 300 and couple the chamber body 300 to the exhaust conduit 110, and the injection flange 202 couple a gate valve 214 and a substrate transfer robot 216 to the chamber body 300. In certain examples the ceramic material 302 may include a transparent ceramic material, such as a ceramic material transparent to electromagnetic radiation within an infrared waveband. Examples of suitable transparent materials include quartz, fused silica, and sapphire. Although shown and described herein as having a particular number of external ribs 318, it is to be understood and appreciated that the chamber body 300 may have fewer or additional external ribs than shown and described herein and remain within the scope of the present disclosure.

The upper heater element array 206 is configured to heat the substrate 2 during deposition of the material layer 4 onto the upper surface 6 of the substrate 2 (e.g., using electromagnetic radiation within an infrared waveband) and in this respect is supported above the chamber body 300, is optically coupled to the interior 316 of the chamber body 300 by the upper wall 304 of the chamber body 300, and includes a plurality of upper heater elements 218. The plurality of upper heater elements 218 may individually include linear filament, may extend laterally above the upper wall 304 of the chamber body 300 and between the first sidewall 308 and the second sidewall 310, and be longitudinally spaced apart from one another between the injection end 312 and the exhaust end 314 of the chamber body 300. The lower heater element array 208 may be similar to the upper heater element array 206, additionally be supported below the chamber body 300, and further include a plurality of lower heater elements 220. The plurality of lower heater elements 220 may extend longitudinally between the injection end 312 and the exhaust end 314 of the chamber body 300, and be laterally spaced apart from one another between the first sidewall 308 and the second sidewall 310 of the chamber body 300. In certain examples, the plurality of lower heater elements 220 may be substantially orthogonal relative to the plurality of upper heater elements 218. In accordance with certain examples, either (or both) the upper heater element array 206 and the lower heater element array 208 may include bull-type lamps and remain within the scope of the present disclosure.

It is contemplated that the chamber arrangement 200 include one or more internal temperature sensor, such as a thermocouple arranged within the chamber body 300, or one or more external temperature sensor such an optical temperature sensor supported outside of the chamber body and optically coupled to an interior 316 of the chamber body 300 through walls of the chamber body 300. In this respect the pyrometer 210 may be configured to acquire temperature measurements of the substrate 2 during deposition of the material layer 4 during deposition of the material layer 4 onto the upper surface 6 of the substrate 2, and may be supported above the chamber body 300. In further respect, the pyrometer 210 may be arranged along an optical axis 222 intersecting a substrate support 224 arranged within the interior 316 of the chamber body 300 and configured to seat thereon the substrate 2, and optically coupled to the interior 316 of the chamber body 300 by the upper wall 304 of the chamber body 300. Temperature measurements may be acquired using electromagnetic radiation emitted by either (or both) the substrate 2 and the material layer 4 during deposition onto the upper surface 6 of the substrate 2 and communicated through the ceramic material 302 forming the upper wall 304 of the chamber body 300 along the optical axis 222. In certain examples, the pyrometer 210 may cooperate with one or more second pyrometer supported above the upper wall 304 of the chamber body 300 and arranged along one or more optical axis (or axes) intersecting the substrate support 224. In accordance with certain examples, the pyrometer 210 may cooperate with one or more quartz pyrometer, e.g., a pyrometer outside of the chamber body 300 and configured to acquire temperature of the ceramic material 302 using electromagnetic radiation emitted by the chamber body 300. Examples of suitable pyrometers include those shown and described in U.S. Patent Application Publication No. 2022/0298672 A1 to M'Saad, filed on Mar. 17, 2022, the contents of which are incorporated herein by reference in its entirety.

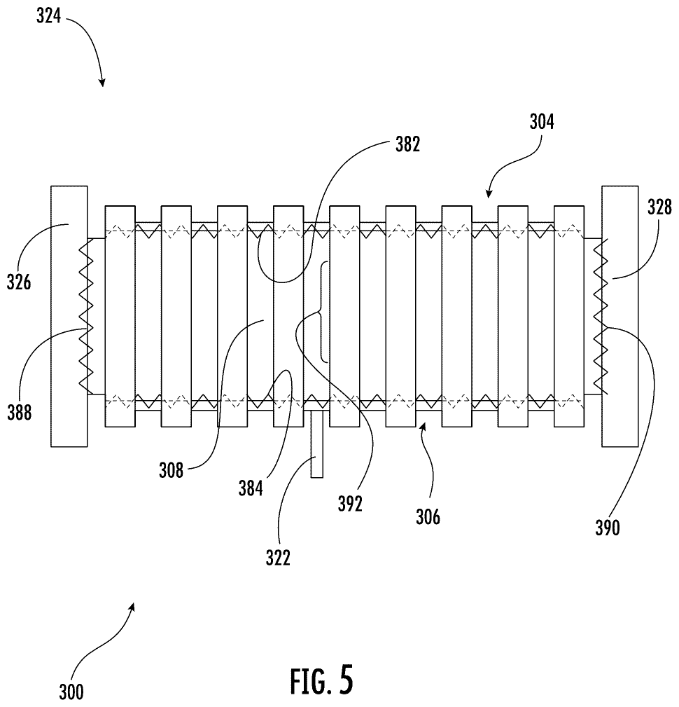

As shown and described herein the chamber arrangement 200 further includes a divider 226, a support member 228, and a shaft member 230. The divider 226 is formed from an opaque material 232, e.g., a material opaque to electromagnetic radiation within an infrared waveband, is seated within the interior 316 of the chamber body 300, divides the interior 316 into an upper chamber 234 and a lower chamber 236, and defines a divider aperture 238 therethrough coupling the upper chamber 234 to the lower chamber 236. The substrate support 224 is supported within the divider aperture 238 for rotation R about a rotation axis 240, may be formed from an opaque material 242, e.g., a material opaque to electromagnetic radiation within an infrared waveband, and is operably associated with the lift and rotate module 212 via the support member 228 and the shaft member 230. In this respect the support member 228 may be arranged along the rotation axis 240 and within the lower chamber 236 of the chamber body 300, and fixed in rotation relative to the substrate support 224. The shaft member 230 may be arranged along the rotation axis 240, extend through a passthrough 320 defined within the lower wall 306 of the chamber body 300, and therefrom within a tubulation body 322 (shown in FIG. 5) protruding from the lower wall 306 below the chamber body 300 and substantially coaxial with the rotation axis 240. In certain examples of the present disclosure either (or both) the opaque material 232 and the opaque material 242 may include a carbonaceous material or a ceramic material. Examples of suitable carbonaceous materials include graphite and pyrolytic carbon; examples of suitable ceramic materials include silicon carbide. In accordance with certain examples, either (or both) the support member 228 and the shaft member 230 may be formed from the ceramic material 302.

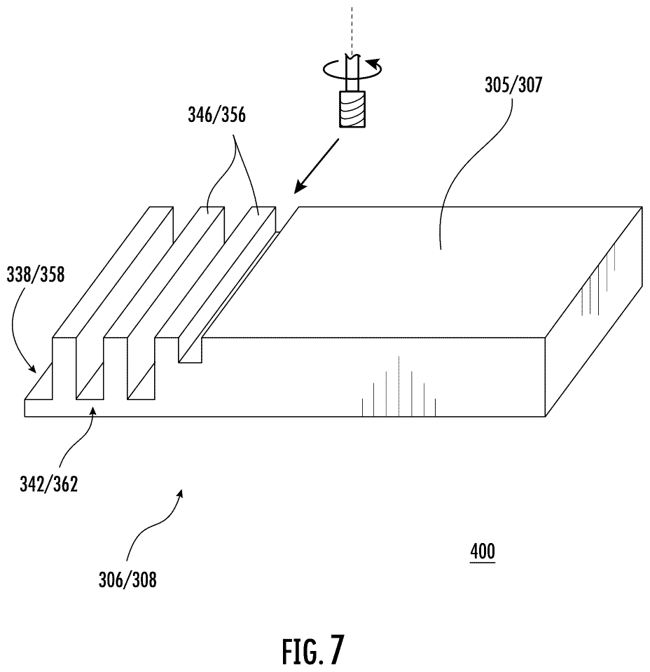

As has been explained above, certain fabrication techniques employed to fabricate chamber bodies may impart artifacts into the structure of the chamber body. For example, welding techniques such as hydrogen (H₂) gas welding may impart residual stress into the ceramic weldment formed using the welding technique due to the localized nature of the heating employed to form the weld. Welding techniques may also cause the ceramic weldment to deviate dimensionally from the intended geometry of the ceramic weldment formed using the welding technique, for example by altering flatness and/or by contour of the resulting fillet formed using the welding technique. Residual stress can stress can generally be relieved using a post-welding annealing operation, albeit at the cost of additional manufacturing cycle time, generally in correspondence with the number of welds that require post-welding anneal. Dimensional deviation may be more resistant to post-welding correction, requiring that dimensional tolerances be widened to reflect the process capability of welding technique employed to fabricate the chamber body and/or greater scrap rates due to dimensional non-conformance. And even then, some material layer deposition processes may be sensitive to welding artifacts, such as welding artifacts imparted into chamber structure optically coupling external heating elements and/or temperature sensors to a substrate during processing. To limit (or eliminate) such artifacts from influence the reliability of the chamber arrangement 200, the chamber body 300 is formed as a weldment 324 having an upper wall 304 formed from a singular quartz workpiece 305 (shown in FIG. 7) using a subtractive manufacturing technique to limit the number of piece parts joined by welds in the ceramic weldment 324.

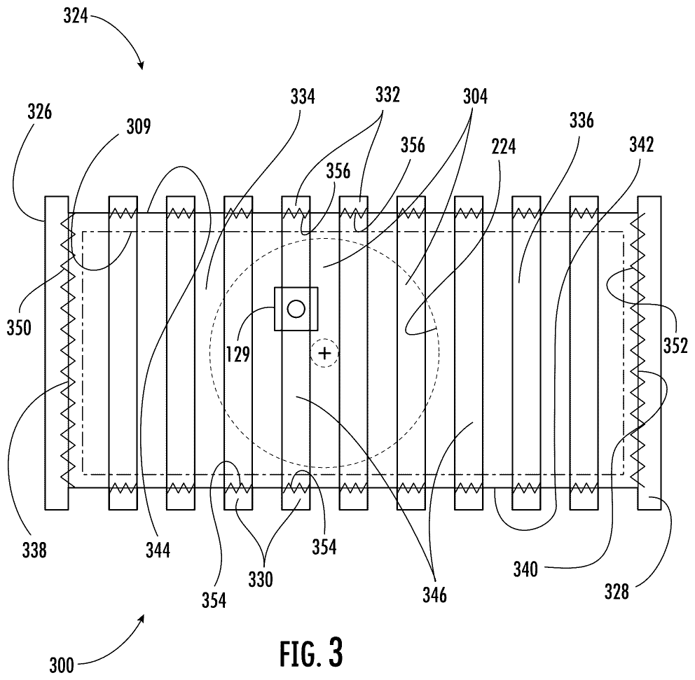

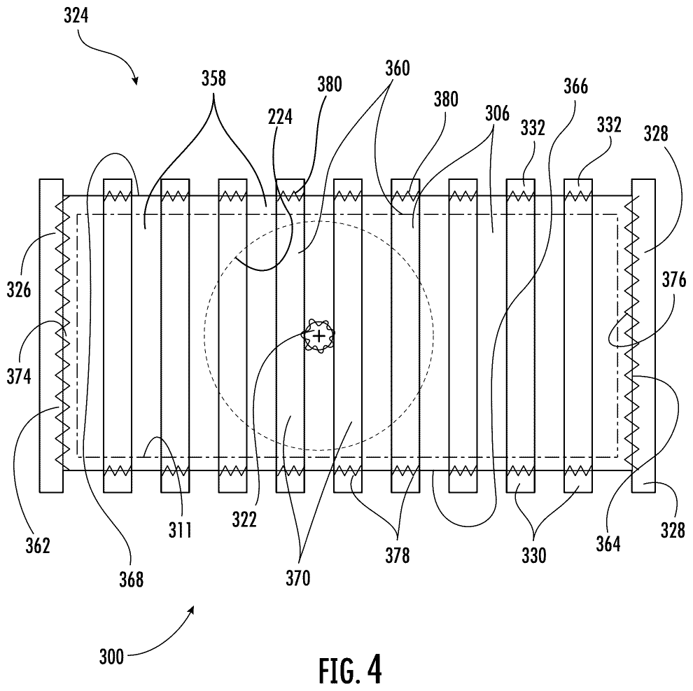

With reference to FIGS. 3-6, the ceramic weldment 324 is shown. The ceramic weldment 324 is formed from (e.g., consists of or consist essentially of) the ceramic material 302 (shown in FIG. 2) and may include the upper wall 304, the lower wall 306, the first sidewall 308, and the second sidewall 310. The ceramic weldment 324 may also include an inject end flange 326, an exhaust end flange 328, a plurality of first side rib segments 330, and a plurality of second side rib segments 332. It is contemplated that the ceramic weldment 324 have an upper wall unwelded ribbed region 309 (shown in FIG. 3) and an unwelded ribbed region 311 (shown in FIG. 4) each defined from a discrete, singular ceramic workpiece using a subtractive manufacturing technique. Advantageously, forming upper wall unwelded ribbed region 309 and the lower wall unwelded ribbed region 311 using a subtractive manufacturing technique can simplify fabrication of the ceramic weldment 324 by limiting the number of welds required to fabricate the ceramic weldment. Forming the upper wall unwelded ribbed region 309 and the lower wall unwelded ribbed region 311 using the subtractive manufacturing technique may also limit the skill level required to fabricate the ceramic weldment 324 due to the dimensional stability imparted by defining ribs using the subtractive manufacturing technique, the ribs resisting deformation during welding operations to couple flanges and side rib segments to the ceramic weldment. To further advantage, forming the upper wall unwelded ribbed region 309 and the lower wall unwelded ribbed region 311 using the subtractive manufacturing technique may improve the optical properties of the regions, the regions being devoid of welding and/or casting artifacts otherwise present were the ribs welded in place or cast in place-the ceramic weldment 324 being uncast in this respect. As used herein the term “weld” means a thermal bond, link or structure that joins two elements through a process that involves a softening or melting of a ceramic material within at least one of the elements such that the materials of the elements are secured to each other when cooled, the welded elements thereby being structurally secured to one another when cooled. Although shown and described herein as having certain elements it is to be understood and appreciated that the ceramic weldment 324 may include additional elements and/or exclude elements shown and described herein in other examples of the present disclosure and remain within the scope of the present disclosure.

Referring to FIG. 3, a portion of the ceramic weldment 324 including the upper wall 304 is shown. It is contemplated that the ceramic weldment 324 may have a unitary, one-piece machined construction. In this respect it is contemplated that the upper wall 304 has (e.g., consist of or consist essentially of) an upper wall plate portion 334 and an upper wall rib portion 336 defining the upper wall unwelded ribbed region 309. The upper wall plate portion 334 extends longitudinally between an inject lateral edge 338 and an exhaust lateral edge 340 longitudinally opposite the inject lateral edge 338. The upper wall plate portion 334 further extends laterally between a first longitudinal edge 342 and a second longitudinal edge 344. The first longitudinal edge 342 couples the inject lateral edge 338 and the exhaust lateral edge 340. The second longitudinal edge 344 is laterally opposite the first longitudinal edge 342, couples the inject lateral edge 338 to the exhaust lateral edge 340, and is separated from the first longitudinal edge 342 by the upper wall rib portion 336 of the upper wall 304. It is contemplated that the upper wall rib portion 336 of the upper wall 304 define a plurality of upper wall rib segments 346 to form portions of the external ribs 318 (shown in FIG. 2) extending about the chamber body 300. As used herein the term “unitary, one-piece machined construction” means a unitary, one-piece, construction with no intervening welds and no welding or casting artifacts that may potentially alter the structure dimensionally or in terms of optical properties.

In certain examples, the first longitudinal edge 342 may be substantially parallel to the second longitudinal edge 344. The first longitudinal edge 342 may be substantially orthogonal relative to the inject lateral edge 338 and/or the exhaust lateral edge 340. In accordance with certain examples, the plurality of upper wall rib segments 346 may be substantially parallel to either (or both) the inject lateral edge 338 and the exhaust lateral edge 340. The plurality of upper wall rib segments 346 may be substantially orthogonal relative to either (or both) the first longitudinal edge 342 and the second longitudinal edge 344 of the upper wall plate portion 334. The plurality of upper wall rib segments 346 may be substantially orthogonal relative to an upper wall interior surface 348 (shown in FIG. 2) bounding the upper chamber 234 (shown in FIG. 2) of the interior 316 (shown in FIG. 2) of the chamber body 300.

The inject end flange 326 is configured to receive thereon the injection flange 202 (shown in FIG. 2) and is longitudinally adjacent the upper wall plate portion 334. The inject end flange 326 is further coupled to the upper wall 304 by an inject end flange-to-upper wall weld 350. The inject end flange-to-upper wall weld 350 extends laterally between the inject end flange 326 and the inject lateral edge 338 of the upper wall plate portion 334 of the upper wall 304. In certain examples, the inject end flange-to-upper wall weld may extend continuously and without interruption along the inject lateral edge 338.

The exhaust end flange 328 is configured to receive thereon the exhaust flange 204 (shown in FIG. 2) and is longitudinally opposite the inject end flange 326. In this respect it is contemplated that the exhaust end flange 328 be separated from the inject end flange 326 by upper wall plate portion 334 and coupled to the upper wall 304 by an exhaust end flange-to-upper wall weld 352. The exhaust end flange-to-upper wall weld 352 is in turn longitudinally separated from the inject end flange-to-upper wall weld 350 by the upper wall rib portion 336 of the upper wall 304. The exhaust end flange-to-upper wall weld 352 further extends laterally between the exhaust end flange 328 and the exhaust lateral edge 340 of the upper wall plate portion 334 of the upper wall 304. In certain examples, the exhaust end flange-to-upper wall weld 352 may extend continuously and without interruption along the exhaust lateral edge 340 of the upper wall plate portion 334 of the upper wall 304.

The plurality of first side rib segments 330 are configured to couple the upper wall rib segments 346 of the upper wall 304 to lower wall rib segments 370 (shown in FIG. 4) to form respective portions of the external ribs 318 (shown in FIG. 2) extending about the chamber body 300 (shown in FIG. 1). In this respect it is contemplated the plurality of first side rib segments 330 may oppose lateral end faces of the upper wall rib segments 346. In further respect, it is also contemplated that the plurality of first side rib segments 330 be coupled to the upper wall rib segments 346 by a plurality of first side rib segment-to-upper wall welds 354, each one of the plurality of first side rib segment-to-upper wall welds 354 coupling one of the plurality of first side rib segments 330 to one of the upper wall rib segment 346.

In certain examples, one or more of the plurality of first side rib segment-to-upper wall welds 354 may extend along only a portion of the lateral end face of the upper wall rib segment 346 coupled to the respective first side rib segment 330 by the one or more of the plurality of first side rib segment-to-upper wall welds 354. In accordance with certain examples, one or more of the plurality of first side rib segment-to-upper wall welds 354 may extend continuously and without interruption along the lateral end face of the upper wall rib segment 346 coupling the respective first side rib segment 330 upper wall rib segment 346. It is contemplated that one or more of the plurality of first side rib segment-to-upper wall welds 354 may also extend along the first longitudinal edge 366 of the upper wall plate portion 334 of the upper wall 304. It is also contemplated that one or more of the plurality of first side rib segment-to-upper wall welds 354 may not couple the first longitudinal edge 366 to the one of the plurality of first side rib segments 330 coupled by the one or more of the plurality of first side rib segment-to-upper wall welds 354, one or more of the plurality of first side rib segments 330 floating with respect to the first longitudinal edge 342 of the upper wall plate portion 334 of the upper wall 304, and remain within the scope of the present disclosure.

The plurality of second side rib segments 332 are similar to the plurality of first side rib segments 330 and in this respect are also configured to couple the upper wall rib segments 346 of the upper wall 304 to lower wall rib segments 370 (shown in FIG. 4) of the lower wall 306 to form respective portions of the external ribs 318 (shown in FIG. 2) extending about the chamber body 300 (shown in FIG. 1). In further respect, it is contemplated that the plurality of second side rib segments 332 oppose lateral end faces of the upper wall rib segments 346 laterally opposite the lateral end faces opposed by the plurality of first side rib segments 330, and that the plurality of second side rib segments 332 be coupled to the upper wall rib segments 346 by a plurality of second side rib segment-to-upper wall welds 356. It is contemplated that each of the plurality of second side rib segment-to-upper wall welds 356 may couple a respective one of the plurality of second side rib segments 332 to a respective one of the plurality of upper wall rib segments 346.

In certain examples, one or more of the plurality of second side rib segment-to-upper wall welds 356 may extend along only a portion of the lateral end face of the upper wall rib segment 346 coupled to the respective second side rib segment 332 by the one or more of the plurality of second side rib segment-to-upper wall welds 356. In accordance with certain examples, one or more of the plurality of second side rib segment-to-upper wall welds 356 may extend continuously and without interruption along the lateral end face of the upper wall rib segment 346 coupled to the respective second side rib segment 332 by the one or more of the plurality of second side rib segment-to-upper wall welds 356. It is contemplated that one or more of the plurality of second side rib segment-to-upper wall welds 356 may extend along the second longitudinal edge 344 of the upper wall plate portion 334 of the upper wall 304, the one or more of the plurality of second side rib segment-to-upper wall welds 356 thereby coupling the respective one of the plurality of second side rib segments 332 to the upper wall plate portion 334 of the upper wall 304. It is also contemplated that one or more of the plurality of second side rib segment-to-upper wall welds 356 may not couple the second longitudinal edge 344 to the one of the plurality of second side rib segments 332 coupled by the one or more of the plurality of second side rib segment-to-upper wall welds 356, one or more of the plurality of second side rib segments 332 floating with respect to the second longitudinal edge 344 of the upper wall plate portion 334 of the upper wall 304, and remain within the scope of the present disclosure.

Referring to FIG. 4, a portion of the ceramic weldment 324 including the lower wall 306 is shown. The lower wall 306 may be similar to the upper wall 304 (shown in FIG. 2) of the chamber body 300 and in this respect may have a unitary, one-piece machined construction. In further respect, the lower wall 306 may have a lower wall plate portion 358 and a lower wall rib portion 360 defining the lower wall unwelded ribbed region 311 formed from a first singular quartz workpiece, e.g., the singular quartz workpiece 305 (shown in FIG. 7), using a subtractive manufacturing technique. The lower wall plate portion 358 extends longitudinally between an inject lateral edge 362 and a longitudinally opposite exhaust lateral edge 364. The lower wall plate portion 358 also extends laterally between a first longitudinal edge 366 and a second longitudinal edge 368 of the lower wall plate portion 358. It is contemplated that the first longitudinal edge 366 couple the inject lateral edge 362 to the exhaust lateral edge 364 of the lower wall plate portion 358. It is also contemplated that the second longitudinal edge 368 also couple the inject lateral edge 338 to the exhaust lateral edge 340 and additionally be laterally separated from the first longitudinal edge 366 by the lower wall rib portion 360 of the lower wall 306. It is further contemplated that the lower wall rib portion 360 of the lower wall 306 extend from the lower wall plate portion 358 of the lower wall 306 in a direction opposite the first sidewall 308 (shown in FIG. 2) and the second sidewall 310 (shown in FIG. 2), that the lower wall rib portion 360 define a plurality of lower wall rib segments 370, and that the plurality of lower wall rib segments 370 be orthogonal relative to the lower wall plate portion 358 of the lower wall 306.

In certain examples the first longitudinal edge 366 of the lower wall plate portion 358 may be substantially parallel to the first longitudinal edge 342 of the upper wall plate portion 334 of the upper wall 304. The first longitudinal edge 366 may also be substantially orthogonal relative to either (or both) of the inject lateral edge 362 of the lower wall plate portion 358 and the exhaust lateral edge 364 of the lower wall plate portion 358. In accordance with certain examples, the second longitudinal edge 368 of the lower wall plate portion 358 may be substantially parallel to the first longitudinal edge 366 of the lower wall plate portion 358. The second longitudinal edge 368 of the lower wall plate portion 358 may also be orthogonal relative to either (or both) the inject lateral edge 362 of the lower wall plate portion 358 and the exhaust lateral edge 364 of the lower wall plate portion 358. It is contemplated that the lower wall rib portion 360 may define a plurality of lower wall rib segments 370. The plurality of lower wall rib segments 370 may be substantially parallel to either (or both) the inject lateral edge 362 and the exhaust lateral edge 364 of the lower wall plate portion 358. The plurality of lower wall rib segments 370 may be substantially orthogonal relative to either (or both) the first longitudinal edge 366 and the second longitudinal edge 368 of the lower wall plate portion 358 of the lower wall 306. The plurality of lower wall rib segments 370 may be substantially orthogonal to a lower wall interior surface 372 (shown in FIG. 2) bounding the lower chamber 236 (shown in FIG. 2) of the interior 316 (shown in FIG. 2) of the chamber body 300.

The inject end flange 326 may oppose the inject lateral edge 362 of the lower wall plate portion 358. The inject end flange 326 may further be coupled to the lower wall plate portion 358 of the lower wall 306 by an inject end flange-to-lower wall weld 374. The inject end flange-to-lower wall weld 374 may extend laterally between the inject end flange 326 and the inject lateral edge 362 of the lower wall plate portion 358. In this respect the inject end flange-to-lower wall weld 374 may extend continuously without interruption between the first sidewall 308 and the second sidewall 310 of the chamber body 300. The exhaust end flange 328 similarly oppose the exhaust lateral edge 364 of the lower wall plate portion 358 and be coupled to the lower wall 306 by an exhaust end flange-to-lower wall weld 376. The exhaust end flange-to-lower wall weld 376 may be longitudinally separated from the inject end flange-to-lower wall weld 374 by the lower wall rib portion 360 of the lower wall 306. The exhaust end flange-to-lower wall weld 376 may extend laterally between the exhaust end flange 328 and the exhaust lateral edge 364 of the lower wall plate portion 358. In this respect the exhaust end flange-to-lower wall weld 376 may extend continuously and without interruption between the first sidewall 308 and the second sidewall 310 of the chamber body 300.

The plurality of first side rib segments 330 may abut the lower wall rib segments 370 of the defined by the lower wall rib portion 360 of the lower wall 306. In this respect the plurality of first side rib segments 330 may be coupled to the lower wall 306 by a plurality of first side rib segment-to-lower wall welds 378. The plurality of first side rib segment-to-lower wall welds 378 may extend between a portion of one of the plurality of first side rib segments 330 and a respective one of the plurality of lower wall rib segments 370. In certain examples, the plurality of first side rib segment-to-lower wall welds 378 may extend between portions of the plurality of first side rib segments 330 and the lower wall rib segments 370 of the lower wall 306. For example, one or more of the plurality of first side rib segment-to-lower wall welds 378 may extend between the or more of the plurality of first side rib segments 330 and the first longitudinal edge 366 of lower wall plate portion 358 of the lower wall 306.

The plurality of second side rib segments 332 may be similar to the plurality of first side rib segments 330 and in this respect may abut the plurality of lower wall rib segments 370 of the lower wall rib portion 360 of the lower wall 306. It is contemplated that the plurality of second side rib segments 332 may abut the plurality of lower wall rib segments 370 at locations laterally opposite the plurality of first side rib segments 330. It is further contemplated that the plurality of second side rib segments 332 may be coupled to the plurality of lower wall rib segments 370 by a plurality of second side rib segment-to-lower wall welds 380. The plurality of second side rib segment-to-lower wall welds 380 may extend between the plurality of lower wall rib segments 370 and the plurality of second side rib segments 332. In certain examples, the one or more of the plurality of second side rib segment-to-lower wall welds 380 may extend only between a respective one of the plurality of second side rib segments 332 and the lower wall plate portion 358 of the lower wall 306. In such examples the one or more of the plurality of second side rib segment-to-lower wall welds 380 may be truncated or shortened with respect the one of the plurality of second side rib segments 332 coupled thereby to the ceramic weldment 324.

Referring to FIG. 5, a portion of the ceramic weldment 324 including the first sidewall 308 is shown. The first sidewall 308 may be coupled to lower wall 306 of the chamber body 300 by a first sidewall-to-upper wall weld 382. The first sidewall-to-upper wall weld 382 may extend longitudinally between the first sidewall 308 and the first longitudinal edge 342 (shown in FIG. 3) of the upper wall plate portion 334 (shown in FIG. 3) of the upper wall 304, for example continuously and without interruption longitudinally between the inject lateral edge 338 (shown in FIG. 3) of the upper wall plate portion 334 (shown in FIG. 3) and the exhaust lateral edge 340 (shown in FIG. 3) of the upper wall plate portion 334. The first sidewall 308 may also be coupled to the lower wall 306 of the chamber body 300 by a first sidewall-to-lower wall weld 384, which may extend between the first sidewall 308 and the first longitudinal edge 366 of the lower wall plate portion 358 (shown in FIG. 4) of the lower wall 306. In certain examples the first sidewall-to-lower wall weld 384 may extend continuously and without interruption longitudinally between the inject lateral edge 362 (shown in FIG. 4) and the exhaust lateral edge 364 (shown in FIG. 4) of the lower wall plate portion 358 of the lower wall 306 of the chamber body 300.

The inject end flange 326 may be coupled to the first sidewall 308 by an inject end flange-to-first sidewall weld 388. The inject end flange-to-first sidewall weld 388 may extend between the inject lateral edge 338 (shown in FIG. 3) of the upper wall plate portion 334 (shown in FIG. 3) of the upper wall 304 and the inject lateral edge 362 (shown in FIG. 4) of the lower wall plate portion 358 (shown in FIG. 4) of the lower wall 306. In this respect the inject end flange-to-first sidewall weld 388 may further extend continuously and without interruption longitudinally along the first sidewall 308 between the inject lateral edge 338 of the upper wall plate portion 334 of the upper wall 304 and the inject lateral edge 362 of the lower wall plate portion 358 of the lower wall 306. The exhaust end flange 328 may be coupled to the first sidewall by an exhaust end flange-to-first sidewall weld 390. The exhaust end flange-to-first sidewall weld 390 may similarly extend between the inject lateral edge 338 of the upper wall plate portion 334 of the upper wall 304 and the inject lateral edge 362 of the lower wall plate portion 358 of the lower wall 306. In certain examples, the exhaust end flange-to-first sidewall weld 390 may extend continuously and without interruption between the inject lateral edge 338 of the upper wall plate portion 334 of the upper wall 304 and the inject lateral edge 362 of the lower wall plate portion 358 of the lower wall 306.

It is contemplated that the plurality of first side rib segments 330 laterally overlay the first sidewall 308. In certain examples the plurality of first side rib segments 330 may float relative to the first sidewall 308. In this respect one or more of the plurality of first side rib segment-to-lower wall welds 378 may be separated from the one of the plurality of first side rib segment-to-upper wall welds 354 coupling a common one of the plurality of first side rib segments 330 to the ceramic weldment 324 by an unwelded rib portion 392 (e.g., weldless), the common one of the plurality of first side rib segments 330 to the ceramic weldment 324 thereby being movable relative to the first sidewall 308. As will be appreciated by those of skill in the art in view of the present disclosure, this may simplify fabrication of the chamber body 300, for example by limiting residual stress (and thereby eliminating the need to anneal the ceramic weldment 324 prior to a subsequent welding event) during fabrication of the ceramic weldment 324 by allowing movement between the plurality of first side rib segments 330 and the first sidewall 308 due to heating during fabrication of the chamber body 300. It may also limit (or eliminate) dimensional change potentially otherwise associated with cyclic heating and cooling of the chamber body 300 during sequential deposition of material layers onto substrates, potentially improving reliability of the semiconductor processing system 100 (shown in FIG. 1) including the chamber arrangement 200 (shown in FIG. 1) with the chamber body 300.

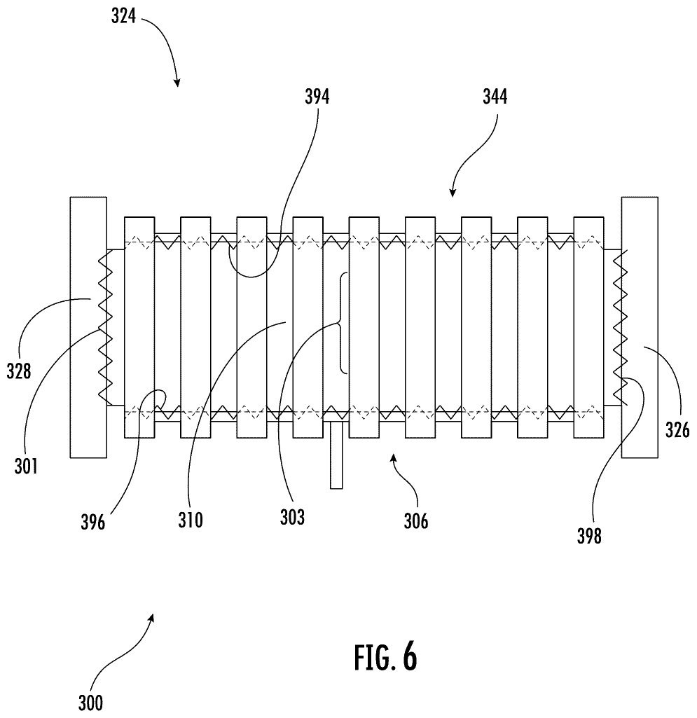

Referring to FIG. 6, a portion of the ceramic weldment 324 including the second sidewall 310 is shown. The second sidewall 310 may be coupled to lower wall 306 of the chamber body 300 by a second sidewall-to-upper wall weld 394. The second sidewall-to-upper wall weld 394 may extend longitudinally between the second sidewall 310 and the second longitudinal edge 344 (shown in FIG. 3) of the upper wall plate portion 334 (shown in FIG. 3), for example continuously and without interruption longitudinally between the inject lateral edge 338 (shown in FIG. 3) of the upper wall plate portion 334 and the exhaust lateral edge 340 (shown in FIG. 3) of the upper wall plate portion 334. It is contemplated that the second sidewall 310 may also be coupled to the lower wall 306 of the chamber body 300 by a second sidewall-to-lower wall weld 396. The second sidewall-to-lower wall weld 396 may extend between the second sidewall 310 and the second longitudinal edge 368 of the lower wall plate portion 358 (shown in FIG. 4) of the lower wall 306. In certain examples, the second sidewall-to-lower wall weld 396 may extend continuously and without interruption longitudinally along the second sidewall 310 between the inject lateral edge 338 (shown in FIG. 4) and the exhaust lateral edge 364 (shown in FIG. 4) of the lower wall plate portion 358 of the lower wall 306 of the chamber body 300.

The inject end flange 326 may be coupled to the second sidewall 310 by an inject end flange-to-second sidewall weld 398. The inject end flange-to-second sidewall weld 398 may extend between the inject lateral edge 338 (shown in FIG. 3) of the upper wall plate portion 334 (shown in FIG. 3) of the upper wall 304 and the inject lateral edge 362 (shown in FIG. 4) of the lower wall plate portion 358 (shown in FIG. 4) of the lower wall 306. The inject end flange-to-second sidewall weld 398 may further extend continuously and without interruption longitudinally along the second sidewall 310 between the inject lateral edge 338 of the upper wall plate portion 334 of the upper wall 304 and the inject lateral edge 362 of the lower wall plate portion 358 of the lower wall 306. It is contemplated that the exhaust end flange 328 may be coupled to the first sidewall by an exhaust end flange-to-second sidewall weld 301. The exhaust end flange-to-second sidewall weld 301 may similarly extend along the second sidewall 310 between the inject lateral edge 338 of the upper wall plate portion 334 of the upper wall 304 and the inject lateral edge 362 of the lower wall plate portion 358 of the lower wall 306. In certain examples, the exhaust end flange-to-second sidewall weld 301 may extend continuously and without interruption between the inject lateral edge 338 of the upper wall plate portion 334 of the upper wall 304 and the inject lateral edge 362 of the lower wall plate portion 358 of the lower wall 306.

It is contemplated that the plurality of second side rib segments 332 laterally overlay the second sidewall 310. In certain examples the plurality of second side rib segments 332 may float relative to the second sidewall 310. In this respect at least one the plurality of second side rib segment-to-lower wall welds 380 may be separated from the one of the plurality of second side rib segment-to-upper wall welds 356 coupling a common one of the plurality of second side rib segments 332 to the ceramic weldment 324 by an unwelded second side rib portion 303, the common one of the plurality of second side rib segments 332 to the ceramic weldment 324 thereby being movable relative to the second sidewall 310. As has been stated above, coupling one or more of the plurality of second side rib segments 332 only partially such that a portion of the one or more second side rib segment 332 floats relative to the second sidewall 310 can further simplify fabrication of the chamber body 300 by limiting residual stress within the ceramic weldment 324 during fabrication, thereby limiting (or eliminating) the need to anneal the ceramic weldment 324 between certain welding operations. As has also been stated above, coupling one or more of the plurality of second side rib segments 332 only partially such that a portion of the one or more second side rib segment 332 floats relative to the second sidewall 310 can also limit (or eliminate) dimensional change potentially otherwise associated with cyclic heating and cooling of the chamber body 300 during sequential deposition of material layers onto substrates, improving reliability of the semiconductor processing system 100 (shown in FIG. 1) including the chamber arrangement 200 (shown in FIG. 1) with the chamber body 300.

With reference to FIGS. 7-12, operations of an example of a method 400 of making the ceramic weldment for a chamber body, e.g., the ceramic weldment 324 (shown in FIG. 3) of the chamber body 300 (shown in FIG. 1), is shown. Referring to FIG. 7, it is contemplated that the upper wall 304 of the chamber body 300 (shown in FIG. 1) be formed from a singular quartz workpiece 305 using a subtractive manufacturing technique to limit the number of discrete piece parts joined during assembly of the chamber body 300. In this respect it contemplated that the plurality of upper wall rib segments 346 be defined using a machining operation. It is contemplated that the machining operation employed to form the plurality of upper wall rib segments 346 further define both the upper wall rib portion 336 and the upper wall plate portion 334 of the upper wall 304. In certain examples, the machining operation (or another machining operation) may the employed to define one or more of the inject lateral edge 338 (shown in FIG. 3) of the upper wall plate portion 334, the exhaust lateral edge 340 (shown in FIG. 3) of the upper wall plate portion 334, the first longitudinal edge 342 of the upper wall plate portion 334, the second longitudinal edge 344 (shown in FIG. 3) of the upper wall plate portion 334, and the upper wall interior surface 348 (shown in FIG. 2) of the upper wall plate portion 334. It is further contemplated that the machining operation define the plurality of upper wall rib segments 346 such that each is substantially parallel to the other, are substantially parallel to the inject lateral edge 338 and the exhaust lateral edge 340 of the upper wall plate portion 334, and are substantially orthogonal relative to the first longitudinal edge 342 and the second longitudinal edge 344 of the upper wall plate portion 334 of the upper wall 304. Non-limiting examples of machining processes that may be employed to form the upper wall plate portion 334 and the upper wall rib portion 336 of the upper wall 304 include milling, core-drilling, sawing, grinding, and lapping.

In certain examples, each of twelve (12) upper wall rib segments 346 are defined from the singular quartz workpiece 305 using the subtractive manufacturing technique. In accordance with certain examples, the lower wall 306 of the chamber body 300 may also (or alternatively) be formed using the subtractive manufacturing technique. In this respect the machining operation may similarly be employed to form the lower wall plate portion 358 and the lower wall rib portion 360 of the lower wall 306 from a second singular quartz workpiece, for example a singular quartz workpiece 307. In such examples the plurality of lower wall rib segments 370 may be formed such that each is substantially parallel to one another, are substantially parallel to the inject lateral edge 338 (shown in FIG. 4) and the exhaust lateral edge 364 (shown in FIG. 4) of the lower wall plate portion 358 of the lower wall 306, and are substantially orthogonal relative to the first longitudinal edge 366 (shown in FIG. 4) and the second longitudinal edge 368 (shown in FIG. 4) of the lower wall plate portion 358 of the lower wall 306. As will be appreciated by those of skill in the art in view of the present disclosure, forming either (or both) the upper wall 304 and the lower wall 306 avoids coupling discrete rib segments to the ceramic weldment 324 (shown in FIG. 3) using discrete welds and associated welding operations, limiting time and associated costs required to fabricate the ceramic weldment 324. As will also be appreciated by those of skill in the art in view of the present disclosure, forming either (or both) the upper wall 304 and lower wall 306 using the subtractive manufacturing technique also avoids the need to anneal either (or both) the upper wall 304 and lower wall 306 subsequent to welding to relieve residual stress. Limiting the need to anneal the ceramic weldment 324 during fabrication in turn may limiting time and associated costs required to fabricate the ceramic weldment 324 included in the chamber body 300 (shown in FIG. 1).

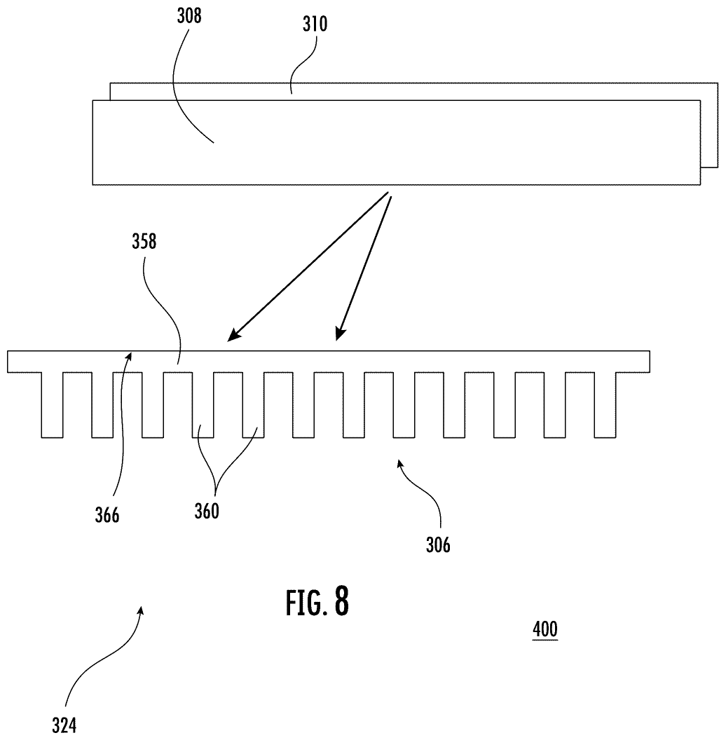

Referring to FIG. 8, once the lower wall 306 is formed, the first sidewall 308 and the second sidewall 310 may be coupled to the lower wall 306 by welds. In this respect it is contemplated that the first sidewall 308 be coupled to the lower wall 306 by forming the first sidewall-to-lower wall weld 384 (shown in FIG. 5) between the first sidewall 308 and the first longitudinal edge 366 (shown in FIG. 4) of the lower wall plate portion 358 of the lower wall 306. The second sidewall 310 (shown in FIG. 2) may similarly be coupled to the lower wall plate portion 358 of the lower wall 306 by forming the second sidewall-to-lower wall weld 396 (shown in FIG. 6) between the second sidewall 310 and the second longitudinal edge 368 (shown in FIG. 4) of the lower wall 306. In certain examples, either (or both) the first sidewall-to-lower wall weld 384 and the second sidewall-to-lower wall weld 396 may be formed using a hydrogen (H₂) gas welding technique. Advantageously, using a hydrogen (H₂) gas welding technique may limit (or eliminate) risk that contamination infiltrate the material forming either (or both) the first sidewall-to-lower wall weld 384 and the second sidewall-to-lower wall weld 396 due to the absence of combustion products (absent water vapor) generated during hydrogen (H₂) gas welding.

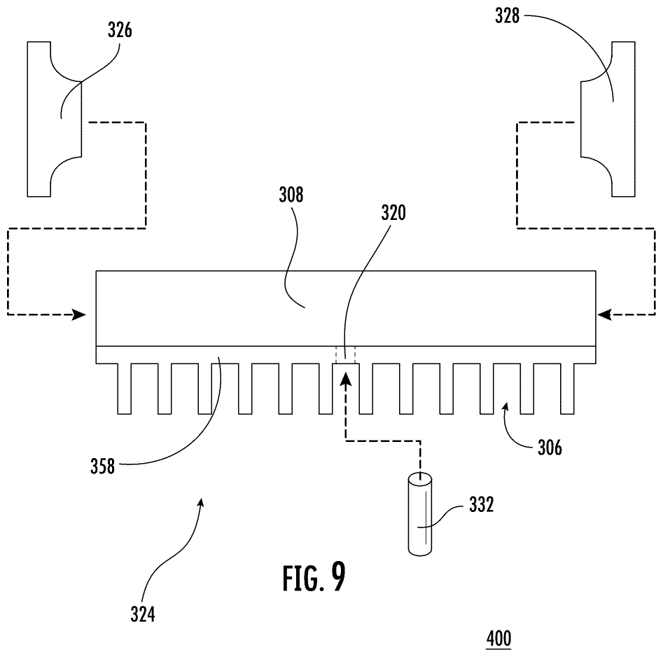

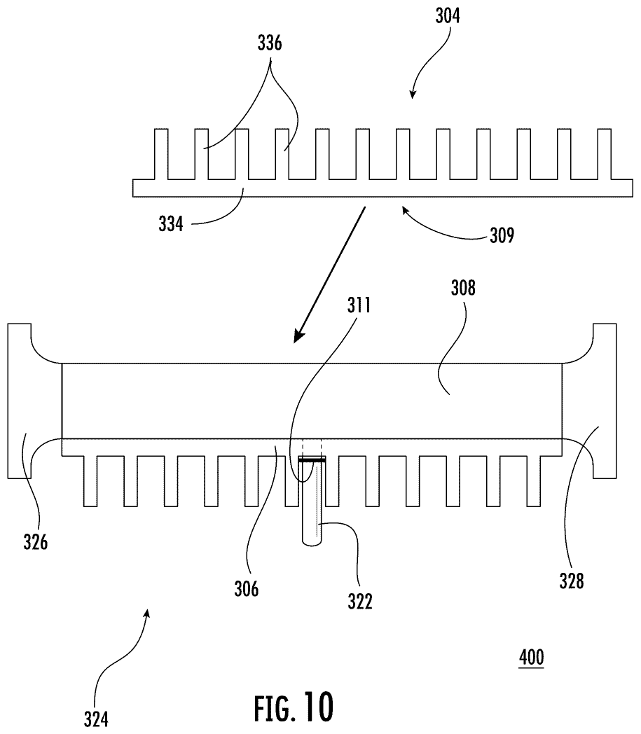

Referring to FIG. 9, once the first sidewall 308 and the second sidewall 310 are coupled to the lower wall 306 by the first sidewall-to-lower wall weld 384 (shown in FIG. 5) and the second sidewall-to-lower wall weld 396 (shown in FIG. 6), the inject end flange 326 and the exhaust end flange 328 may be coupled to weldment 324. In this respect the inject end flange 326 may be coupled to the inject lateral edge 362 (shown in FIG. 4) of the lower wall 306 by forming the inject end flange-to-lower wall weld 374 (shown in FIG. 4) between the inject end flange 326 and the inject lateral edge 362 of the lower wall 306. In further respect, the inject end flange 326 may be coupled to the first sidewall 308 by forming the inject end flange-to-first sidewall weld 388 (shown in FIG. 5) between the inject end flange 326 and the first sidewall 308, and the inject end flange 326 further coupled to the second sidewall 310 (shown in FIG. 2) by forming the inject end flange-to-second sidewall weld 398 (shown in FIG. 6) between the inject end flange 326 and the second sidewall 310. The exhaust end flange 328 may similarly be coupled to the ceramic weldment 324 by forming the exhaust end flange-to-lower wall weld 376 (shown in FIG. 4) between the exhaust end flange 328 and the exhaust lateral edge 364 (shown in FIG. 4) of the lower wall 306, forming the exhaust end flange-to-first sidewall weld 390 (shown in FIG. 5) between the exhaust end flange 328 and the first sidewall 308, and forming the exhaust end flange-to-second sidewall weld 301 (shown in FIG. 6) between the exhaust end flange 328 and the second sidewall 310. In certain examples, the passthrough 320 may then be defined within the lower wall 306, for example using a drilling or boring process, and the tubulation body 322 then coupled to the lower wall 306 by registering the tubulation body 322 to the passthrough 320 and thereafter forming a tubulation body-to-lower wall weld 311 (shown in FIG. 10). As above, one or more of the aforementioned welds may be formed using a hydrogen (H₂) gas welding technique.

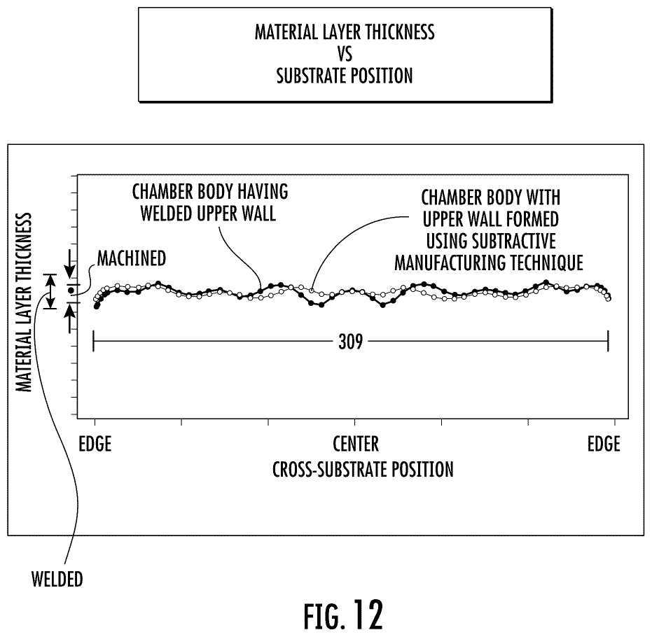

Referring to FIG. 10, once the inject end flange 326 and the exhaust end flange 328 are coupled to the ceramic weldment 324, the upper wall 304 may be joined to the ceramic weldment 324. Coupling may be accomplished by registering the upper wall 304 to the first sidewall 308, the second sidewall 310 (shown in FIG. 2), the inject end flange 326, and the exhaust end flange 328. Once registered, the first sidewall-to-upper wall weld 382 (shown in FIG. 5) may be formed between the first sidewall 308 and the first longitudinal edge 366 (shown in FIG. 4) upper wall plate portion 334 of the upper wall 304, the second sidewall-to-upper wall weld 394 (shown in FIG. 6) formed between the second sidewall 310 and the second longitudinal edge 368 (shown in FIG. 4) of the upper wall plate portion 334 of the upper wall 304, the inject end flange-to-upper wall weld 350 (shown in FIG. 3) formed between the inject end flange 326 and the inject lateral edge 338 of the upper wall plate portion 334 of the upper wall 304, and the exhaust end flange-to-upper wall weld 352 (shown in FIG. 3) formed between the exhaust end flange 328 and the exhaust lateral edge 340 (shown in FIG. 3) of the upper wall plate portion 334 of the upper wall 304. Advantageously, once formed, the upper wall 304 defines the unwelded ribbed region 309 (shown in FIG. 3) overlaying and extending about the passthrough 320 (shown in FIG. 2), the unwelded ribbed region 309 for example having a diameter of at least 300 millimeters extending about the passthrough 320. Unexpectedly, as shown in FIG. 12, the unwelded ribbed region 309 may limit cross-substrate material layer variation in certain material layers by 25% or more in comparison to weldments having welded upper ribs due to an absence of optical effects (e.g., scattering and/or refraction) in the ceramic weldment 324 within the unwelded ribbed region 309 in comparison the chamber bodies having welds overlaying the substrate support arranged within the interior of the chamber body.

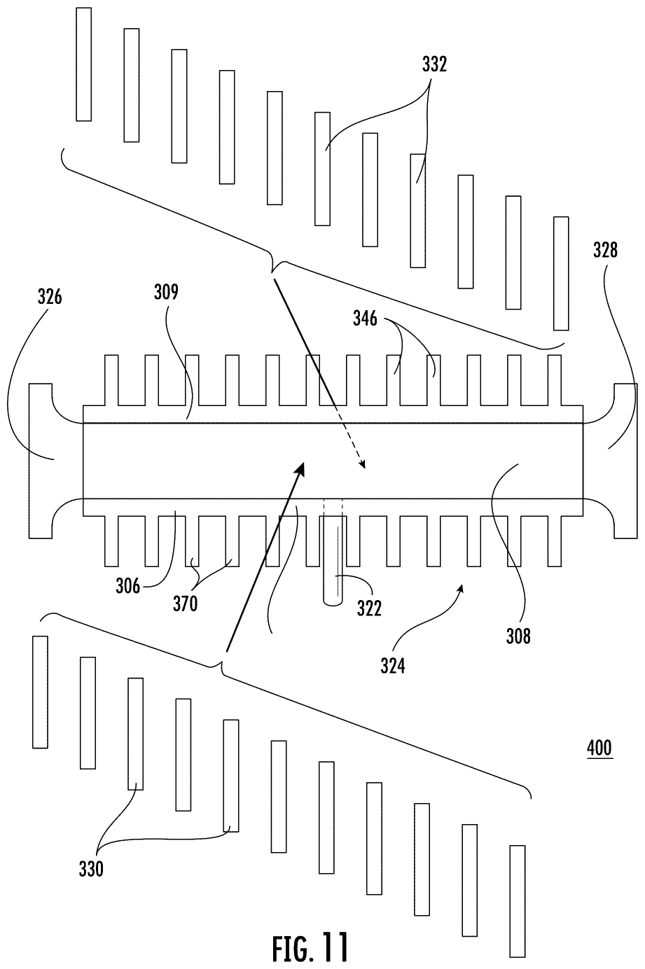

With reference to FIG. 11, the plurality of first side rib segments 330 and the plurality of second side rib segments 332 are shown being coupled to the ceramic weldment 324 is shown. Coupling of the first plurality of first side rib segments 330 may be accomplished by registering a first of the plurality of first side rib segments 330 to the ceramic weldment 324 such that the one of the plurality of first side rib segments 330 laterally overlays one of the plurality of upper wall rib segments 346 and one of the plurality of lower wall rib segments 370, and overlays a portion of the first sidewall 308 intermediate the one of the plurality of upper wall rib segments 346 and the one of the plurality of lower wall rib segments 370. So registered, a first of the plurality of first side rib segment-to-upper wall welds 354 (shown in FIG. 3) may formed between the first of the plurality of first side rib segments 330 and the one of the plurality of upper wall rib segments 346, and a first of the plurality of first side rib segment-to-lower wall welds 378 formed between the first of the plurality of first side rib segments 330 and the one of the plurality of upper wall rib segments 346. It is contemplated that the remainder of the plurality of first side rib segments 330 may be sequentially thereafter registered the ceramic weldment 324 between the plurality of upper wall rib segments 346 and the plurality of lower wall rib segments 370, with or without intervening anneal operations, as appropriate in view of associated residual stress imparted into the ceramic weldment 324.

Coupling of the second plurality of second side rib segments 332 may similarly be accomplished by registering a first of the plurality of the second side rib segments 332 to the ceramic weldment 324 such that the one of the plurality of second side rib segments 332 laterally overlays one of the plurality of upper wall rib segments 346 and one of the plurality of lower wall rib segments 370 laterally opposite one of the plurality of first side rib segments 330, and overlays a portion of the second sidewall 310 intermediate the one of the plurality of upper wall rib segments 346 and the one of the plurality of lower wall rib segments 370. So registered, a first of the plurality of second side rib segment-to-upper wall welds 356 (shown in FIG. 3) may formed between the first of the plurality of second side rib segments 332 and the one of the plurality of upper wall rib segments 346, and a first of the plurality of second side rib segment-to-lower wall welds 380 similarly formed between the first of the plurality of second side rib segments 332 and the one of the plurality of upper wall rib segments 346. It is contemplated that the remainder of the plurality of second side rib segments 332 may thereafter be sequentially thereafter registered the ceramic weldment 324 between the plurality of upper wall rib segments 346 and the plurality of lower wall rib segments 370, with or without intervening anneal operations.

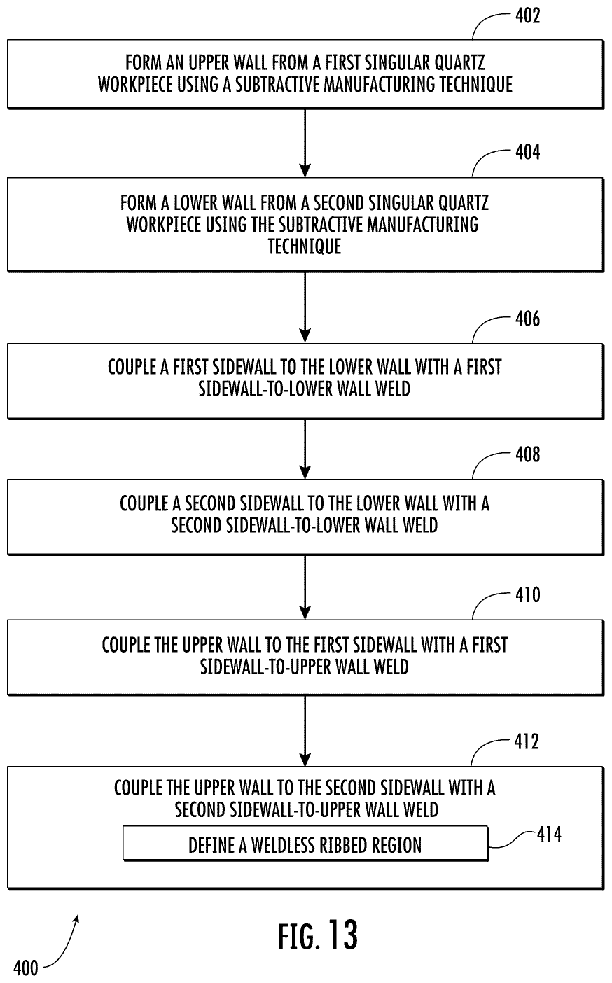

With reference to FIGS. 13-15, the method 400 of making a chamber body, e.g., the chamber body 300 (shown in FIG. 1), is shown. Referring to FIG. 13, the method 400 may include forming an upper wall having a lower wall plate portion and a lower wall rib portion from a singular quartz workpiece using a subtractive manufacturing technique, e.g., forming the upper wall 304 (shown in FIG. 2) having the upper wall plate portion 334 (shown in FIG. 7) and the upper wall rib portion 336 (shown in FIG. 7) from the singular quartz workpiece 305 (shown in FIG. 7), as shown with box 402. The method 400 may also include forming a lower wall having a lower wall plate portion and a lower wall rib portion from a singular quartz workpiece using the subtractive manufacturing technique, e.g., the lower wall 306 (shown in FIG. 2) having the lower wall plate portion 358 (shown in FIG. 7) and the lower wall rib portion 360 (shown in FIG. 7) from the singular quartz workpiece 307 (shown in FIG. 7), as shown with box 404.

It is contemplated that method 400 include forming a weldment using a welding technique, e.g., the ceramic weldment 324 (shown in FIG. 3), for example as shown with boxes 406-412. As shown with box 406, the method 400 may include coupling a first sidewall be coupled to the lower wall plate portion using a first sidewall-to-lower wall weld, e.g., the first sidewall 308 (shown in FIG. 2) to the lower wall plate portion using the first sidewall-to-lower wall weld 384 (shown in FIG. 5). As shown with box 408, the method 400 may also include coupling a second sidewall to the lower plate portion of the lower wall using a lower wall-to-lower plate portion weld, e.g., the second sidewall 310 (shown in FIG. 3) to the lower wall plate portion of the lower wall using the second sidewall-to-lower wall weld 396 (shown in FIG. 6), as shown with box 408. As shown with box 410, the method 400 may additionally include coupling the upper wall to the first sidewall by forming an upper wall-to-first sidewall weld between the upper wall plate portion of the upper wall and the first sidewall, e.g., the first sidewall-to-upper wall weld 382 (shown in FIG. 5). As shown with box 412, the method 400 may additionally include coupling the upper wall to the second sidewall by forming an upper wall-to-second sidewall weld between the upper wall plate portion of the upper wall and the second sidewall, e.g., the second sidewall-to-upper wall weld 394 (shown in FIG. 6), as shown with box 414. Advantageously, once coupled to the first sidewall and the second sidewall, the upper wall may define a unwelded ribbed region overlaying an interior of the chamber body, e.g., the unwelded ribbed region 309 (shown in FIG. 3) overlying the interior 316 (shown in FIG. 2) of the chamber body, as shown with box 414. The unwelded ribbed region 309 may have fewer welding artifacts than other regions of the upper wall, for example a laterally peripheral region laterally adjacent to the first sidewall and/or the second sidewall and/or a longitudinally peripheral region laterally adjacent to the inject end flange and/or the exhaust end flange, e.g., the inject end flange 326 (shown in FIG. 3) and/or the exhaust end flange 328 (shown in FIG. 3), as also shown with box 414.

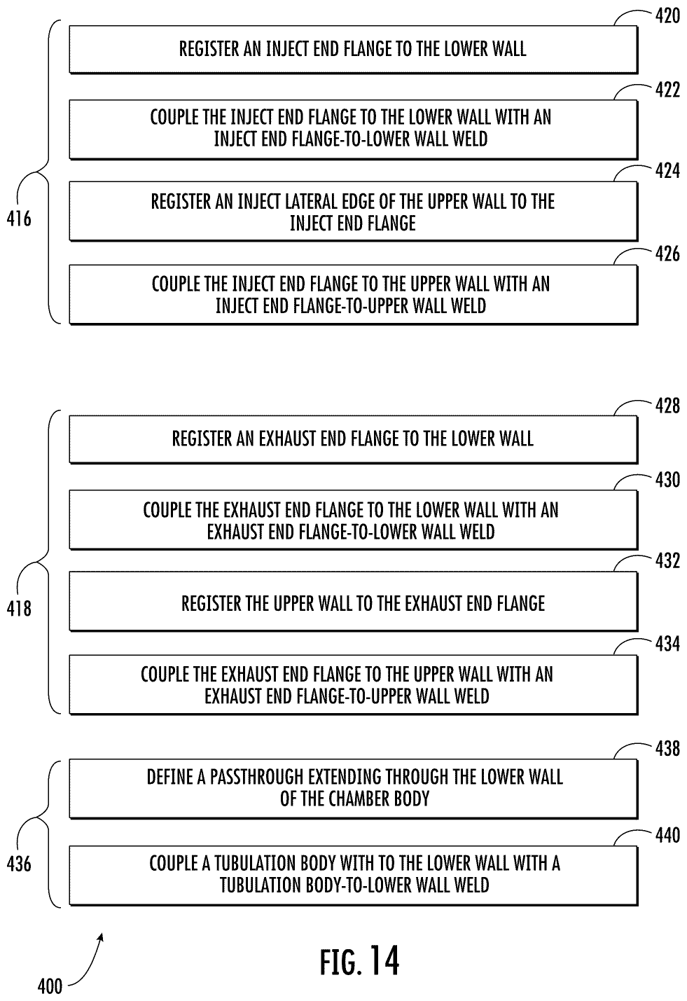

Referring to FIG. 14, it is contemplated that the method 400 include coupling the inject end flange and the exhaust end flange to the ceramic weldment, as shown with bracket 416 and with bracket 418. In this respect the method 400 may include registering the inject end flange to the lower wall of the chamber body, for example to the lower wall plate portion of the lower wall, as shown with box 420. In further respect, the method 400 may also include registering an inject lateral edge of the upper wall to the inject end flange, e.g., the inject lateral edge 338 (shown in FIG. 3), as shown with box 424. Once the inject end flange is registered to the lower wall of the chamber body the inject end flange may be coupled to the lower wall using an inject end flange-to-lower wall weld, e.g., the inject end flange-to-lower wall weld 374 (shown in FIG. 4), as shown with box 422. Similarly, once the upper wall is registered to the inject end flange, the inject end flange may be coupled the upper wall by an inject end flange-to-upper wall weld, e.g., the inject end flange-to-upper wall weld 350 (shown in FIG. 3), as shown with box 426. It is also contemplated that the inject end flange be coupled to the first sidewall by an inject end flange-to-first sidewall weld, e.g., the inject end flange-to-first sidewall weld 388 (shown in FIG. 5), and that the inject end flange further be coupled to the second sidewall by an inject end flange-to-second sidewall weld 398 (shown in FIG. 5), as also shown with bracket 416.

It is contemplated that the method 400 may further include registering the exhaust end flange to the lower wall of the chamber body, for example to the lower wall plate portion of the lower wall, as shown with box 428. It is also contemplated that the method 400 include registering an exhaust lateral edge of the upper wall to the inject end flange, e.g., the 340 (shown in FIG. 3) of the upper wall of the chamber body, as shown with box 432. Once is registered to the lower wall of the chamber body the exhaust end flange may be coupled to the lower wall using an exhaust end flange-to-lower wall weld, e.g., the exhaust end flange-to-lower wall weld 376 (shown in FIG. 4), as shown with box 430. Similarly, once the upper wall is registered to the exhaust end flange, the exhaust end flange may be coupled the upper wall by an exhaust end flange-to-upper wall weld, e.g., the exhaust end flange-to-upper wall weld 352 (shown in FIG. 3), as shown with box 434. It is also contemplated that the inject end flange be coupled to the first sidewall by an exhaust end flange-to-first sidewall weld, e.g., the exhaust end flange-to-first sidewall weld 390 (shown in FIG. 5), and that the exhaust end flange be further coupled to the second sidewall by an exhaust end flange-to-second sidewall weld 301 (shown in FIG. 5), as also shown with bracket 416.

As also shown in FIG. 14, the method 400 may include defining a passthrough in the ceramic weldment and coupling a tubulation body to the ceramic weldment, e.g., defining the passthrough 320 (shown in FIG. 4) and coupling the tubulation body 322 (shown in FIG. 4) to the ceramic weldment, as shown with bracket 436. The passthrough may be defined within the lower wall of the chamber body, for example through the lower wall plate portion of the lower wall of the chamber body, as shown with 438. Once the passthrough is defined in the lower wall plate portion of the lower wall, the tubulation body may be registered to the passthrough and coupled to the lower wall by a tubulation body-to-lower wall weld, e.g., the tubulation body-to-lower wall weld 311 (shown in FIG. 4), as shown with box 440. In certain examples, the passthrough may be defined subsequent to the lower wall being defined using the subtractive manufacturing technique, as also shown with box 440. As will be appreciated by those of skill in the art in view of the present disclosure, this can simplify fabrication of the chamber body, for example by avoiding the need to compensate for dimensional changes to the lower resultant from welding of lower ribs the lower wall during forming of the passthrough. In accordance with certain examples the tubulation body may be coupled to the lower wall subsequent to forming the lower wall using the subtractive manufacturing technique. The further advantage, this can also simplify fabrication of the chamber body, for example avoiding the need to compensate for dimensional change to the lower wall plate body during forming of the tubulation body-to-lower wall weld due to the stiffness provided by the lower wall rib portion of the lower wall formed using the subtractive manufacturing technique.

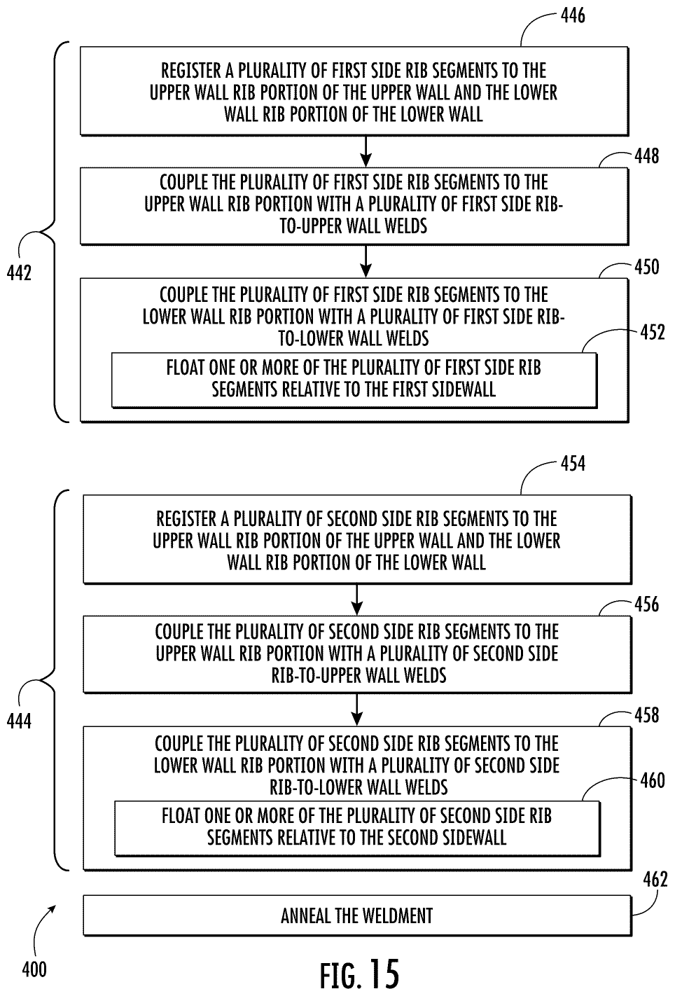

Referring to FIG. 15, it is contemplated that the method 400 may further include coupling a plurality of first side rib segments and a second plurality of side rib segments to the ceramic weldment, e.g., the coupling the plurality of first side rib segments 330 (shown in FIG. 3) and the plurality of second side rib segments 332 (shown in FIG. 3) to the ceramic weldment, as shown with bracket 442 and bracket 444. In this respect the plurality of first side rib segments may be registered to the ceramic weldment, for example by laterally registering the plurality of first side rib segments to upper wall rib segments of the upper wall and to lower wall rib segments of the lower wall, e.g., laterally registering the plurality of first rib segments to the upper wall rib segments 346 (shown in FIG. 3) of the upper wall and the lower wall rib segments 370 (shown in FIG. 3) of the lower wall, as shown with box 446. In further respect, the plurality of first side rib segments may be coupled to the upper wall rib segments by a plurality of first side rib segment-to-upper wall welds, e.g., the plurality of first side rib segment-to-upper wall welds 354 (shown in FIG. 3), and the plurality of first side rib segments may be coupled to the lower wall rib segments by a plurality of first side rib segments-to-lower wall welds, e.g., the plurality of first side rib segment-to-lower wall welds 378 (shown in FIG. 4), as shown with box 448 and box 450. In certain examples, welds coupling one or more of the plurality of first side rib segments may be spaced apart from one another by at least a portion of the first sidewall, one or more first side rib segment floating with respect to the first sidewall, as shown with box 452. Advantageously, floating one or more of the plurality of first side rib segments relative to the first sidewall can limit stress within the ceramic weldment during fabrication, for example by allowing the sidewall to flex responsive to heating, limiting the need to anneal the chamber to relieve residual stress associated with welding. Floating one or more of the plurality of first side rib segments relative to the first sidewall may also limit dimensional change of the chamber body associated with cyclic heating and cooling of the chamber body during processing, potentially extending service life of the chamber body.

Coupling the plurality of second side rib segments may similarly be accomplished by registering the plurality of second side rib segments to the upper wall rib segments of the upper wall and to lower wall rib segments of the lower wall at locations laterally opposite the plurality of first side rib segments, as shown with box 454. Once registered, the plurality of second side rib segments may be coupled to the upper wall rib segments by a plurality of second side rib segment-to-upper wall welds, e.g., the plurality of second side rib segment-to-upper wall welds 356 (shown in FIG. 3), and the plurality of second side rib segments may be coupled to the lower wall rib segments by a plurality of second side rib segments-to-lower wall welds, e.g., the plurality of second side rib segment-to-lower wall welds 380 (shown in FIG. 4), as shown with box 456 and box 458. In certain examples, welds coupling one or more of the plurality of second side rib segments may be spaced apart from one another by at least a portion of the second sidewall, one or more first side rib segment floating with respect to the second sidewall, as shown with box 460. Advantageously, floating one or more of the plurality of second side rib segments relative to the first sidewall may further limit stress within the ceramic weldment during fabrication, for example by similarly allowing the second sidewall to flex responsive to heating, potentially limiting the need to anneal the chamber to relieve residual stress associated with welding. Floating one or more of the plurality of second side rib segments relative to the second sidewall may similarly further limit dimensional change of the chamber body associated with cyclic heating and cooling of the chamber body during processing, also potentially extending service life of the chamber body. As shown box 462, the ceramic weldment may additionally be annealed subsequent to one or more of the aforementioned welding events, though the number and/or duration of one or more of the annealing operation may be smaller due to formation of the upper wall and the lower wall using the subtractive manufacturing techniques described above.

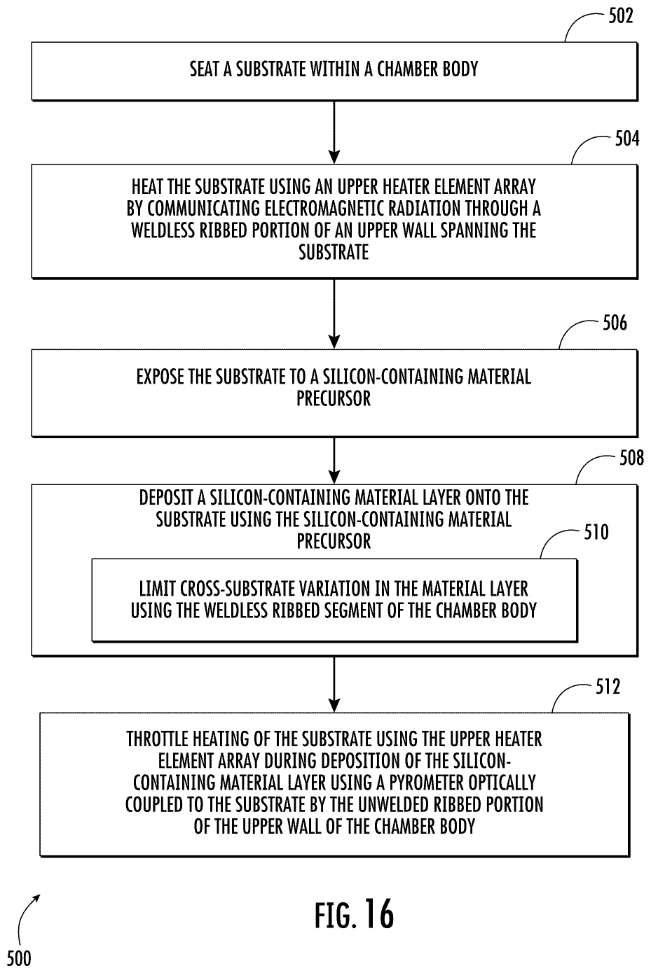

With reference to FIG. 16, a method 500 of depositing a material layer onto a substrate seated within a chamber body having an upper wall formed using a subtractive manufacturing technique, e.g., the material layer 4 (shown in FIG. 1) onto the substrate 2 (shown in FIG. 1) while seated in the chamber body 300 (shown in FIG. 1), is shown. The method 500 includes seating the substrate on a substrate support arranged within the chamber body, e.g. the substrate support 224 (shown in FIG. 16), as shown with box 502. The method 500 further includes heating the substrate using electromagnetic radiation emitted by one or more of an upper heater element array supported above the chamber body and a lower heater element array supported below the chamber body, e.g., one or more of the upper heater element array 206 (shown in FIG. 2) and the lower heater element array 208 (shown in FIG. 2), as shown with box 504. It is contemplated that the electromagnetic radiation be communicated through a unwelded ribbed region of the chamber body, e.g., the unwelded ribbed region 309 (shown in FIG. 3) of the chamber body, as also shown with box 504. It is also contemplated that the substrate be exposed to a silicon-containing material layer precursor, e.g., the material layer precursor 10 (shown in FIG. 1), and that a silicon-containing material layer be deposited onto the substrate using the silicon-containing material layer precursor, as shown with box 506 and box 508. It is further contemplated that heating of the substrate may be throttled during deposition of the material layer using a pyrometer optically coupled to the substrate and/or the material layer by the unwelded ribbed region of the upper wall of the chamber body during deposition onto the upper surface of the substrate, as shown with box 512. Advantageously, either (or both) of the optical coupling of the upper heater array and the pyrometer may limit variation within the material layer by an absence of welds within substantially all of the unwelded ribbed region of the upper wall of the chamber body overlaying the substrate during deposition of the material layer onto the upper surface of the substrate.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

1. A chamber body, comprising:
a ceramic weldment having:
a lower wall;
a sidewall coupled to the lower wall by a sidewall-to-lower wall weld; and
an upper wall coupled to the sidewall by a sidewall-to-upper wall weld,
wherein the upper wall has an upper wall plate portion and an upper wall rib portion extending therefrom formed from a singular quartz workpiece using a subtractive manufacturing technique, the upper wall having a unwelded ribbed region overlying the lower wall.

2. The chamber body of claim 1, wherein the ceramic weldment further comprises:
an inject end flange coupled to the upper wall by an inject end flange-to-upper wall weld;
an exhaust end flange coupled to the upper wall by an exhaust end flange-to-upper wall weld, wherein the ceramic weldment consists essentially of quartz.

3. The chamber body of claim 1, wherein the sidewall is a first sidewall the chamber body has a second sidewall extending in parallel with the first sidewall, the second sidewall coupled to the lower wall by a second sidewall-to-lower wall weld, the second sidewall coupled to the upper wall by the second sidewall-to-upper wall weld.

4. The chamber body of claim 3, wherein the lower wall has a lower wall rib portion extending in a direction opposite the sidewall and the upper wall of the ceramic weldment, the ceramic weldment further having:
a plurality of first side rib segments coupled to the upper wall rib portions by a plurality of first side rib segment-to-upper wall welds, the plurality of first side rib segments coupled to the lower wall rib portion by a plurality of first side rib segment-to-lower wall welds; and
a plurality of second side rib segments coupled to the upper wall rib portion by a plurality of second side rib segment-to-upper wall welds, the plurality of second side rib segments coupled to the lower wall rib portion by a plurality of second side rib segment-to-lower wall welds.

5. The chamber body of claim 3, wherein the lower wall has a lower wall plate portion separating the lower wall rib portion from the first sidewall and the second sidewall, and wherein the lower wall plate portion and the lower wall rib portion are formed from another singular quartz workpiece using the subtractive manufacturing technique.

6. The chamber body of claim 1, wherein the lower wall defines a passthrough, and further comprising a tubulation body registered to the passthrough and coupled to the lower wall at the passthrough by a tubulation body-to-lower wall weld.

7. The chamber body of claim 6, wherein the upper wall has an upper wall unwelded ribbed region defined using the subtractive manufacturing technique extending about the passthrough, and wherein the upper wall unwelded ribbed region has a diameter greater than 300 millimeters.

8. The chamber body of claim 6, wherein the lower wall has a lower wall unwelded ribbed region extending about the passthrough, and wherein the lower wall unwelded ribbed region is bounded by a first sidewall-to-lower wall weld and a second sidewall-to-lower wall weld that is laterally opposite the first sidewall-to-lower wall weld.

9. The chamber body of claim 8, wherein the lower wall unwelded ribbed region is bounded by an inject end flange-to-lower wall weld and an exhaust end flange-to-lower wall weld that is longitudinally opposite the inject end flange-to-lower wall weld.

10. A chamber arrangement, comprising:
a chamber body as recited in claim 1, wherein the lower wall defines a passthrough and the chamber body further comprises a tubulation body registered to the passthrough and coupled to the lower wall by a tubulation body-to-lower wall weld;
a substrate support arranged within an interior of the chamber body and supported for rotation about a rotation axis extending through the passthrough;
a support member arranged along the rotation axis and fixed in rotation relative to the substrate support; and
a shaft member arranged along the rotation axis and fixed in rotation relative to the support member,
wherein the shaft member extends through the passthrough and the tubulation body to operably couple a lift and rotate module to the substrate support.

11. The chamber arrangement of claim 10, wherein the lower wall has an upper wall unwelded ribbed region extending about the passthrough, the chamber arrangement further comprising an upper heater element array with a plurality of upper heater elements supported above the upper wall of the chamber body and overlying the substrate support, and wherein the upper wall unwelded ribbed region optically couples the plurality of upper heater elements to the interior of the chamber body.

12. The chamber arrangement of claim 11, further comprising a pyrometer supported above the chamber body and arranged along an optical axis intersecting the substrate support, wherein the upper wall unwelded ribbed region optically coupled the pyrometer to the interior of the chamber body.

13. A semiconductor processing system, comprising:
a chamber arrangement including a chamber body as recited in claim 1, wherein the chamber arrangement further comprises a substrate support arranged within an interior of the chamber body and configured to support a substrate during deposition of a material layer onto an upper surface of the substrate;
a precursor source including a silicon-containing material layer precursor coupled to an injection end of the chamber body; and
an exhaust source including a vacuum pump coupled to an exhaust end of the chamber body and therethrough to the precursor source.

14. A method of making a ceramic weldment for a chamber body, the method comprising:
forming an upper wall having an upper wall plate portion and an upper wall rib portion extending from the upper wall plate portion from a first singular quartz workpiece using a subtractive manufacturing technique;
forming a lower wall having a lower wall plate portion and a lower wall rib portion extending from the lower wall plate portion from a second singular quartz workpiece using the subtractive manufacturing technique;
coupling a first sidewall to a lower wall with a first sidewall-to-lower wall weld;
coupling a second sidewall to the lower wall with a second sidewall-to-lower wall weld;
coupling the upper wall plate portion of the upper wall to the first sidewall with a first sidewall-to-upper wall weld; and
coupling the upper wall plate portion of the upper wall to the second sidewall with a second sidewall-to-upper wall weld, whereby the upper wall defines a unwelded ribbed region overlying the lower wall and separated from the lower wall by the first side wall and the second sidewall.

15. The method of claim 14, further comprising:
registering an inject end flange to an inject lateral edge of the lower wall plate portion of the lower wall and coupling the inject end flange to the lower wall with an inject end flange-to-lower wall weld; and
registering an inject lateral edge of the upper wall to the inject end flange and coupling the inject end flange to the upper wall with an inject end flange-to-upper wall weld.

16. The method of claim 15, further comprising:
registering an exhaust end flange to an exhaust lateral edge of the lower wall plate portion of the lower wall and coupling the exhaust end flange to the lower wall with an exhaust end flange-to-lower wall weld; and
registering an exhaust lateral edge of the upper wall to the exhaust end flange and coupling the exhaust end flange to the upper wall with an exhaust end flange-to-upper wall weld.

17. The method of claim 16, further comprising:
defining a passthrough extending through the lower wall of the chamber body; and
coupling a tubulation body to the lower wall with a tubulation body-lower wall weld, whereby the upper wall unwelded ribbed region overlays and extends about the passthrough.

18. The method of claim 14, further comprising:
registering a plurality of first side rib segments to the upper wall rib portion of the upper wall and the lower wall rib portion of the lower wall;
coupling the plurality of first side rib segments to the upper wall rib portion with a plurality of first side rib-to-upper wall welds; and
coupling the plurality of first side rib segments to the lower wall rib portion with a plurality of first side rib-to-lower wall welds, whereby one or more of the plurality of first side rib segments floats relative to the first sidewall.

19. The method of claim 18, further comprising:
annealing the ceramic weldment;
registering a plurality of second side rib segments to the upper wall rib portion of the upper wall and the lower wall rib portion of the lower wall;
coupling the plurality of second side rib segments the to the upper wall rib portion with a plurality of second side rib-to-upper wall welds; and
coupling the plurality of second side rib segments to the lower wall rib portion with a plurality of second side rib-to-lower wall welds, whereby one or more of the plurality of second side rib segments floats relative to the second sidewall.

20. The method of claim 14, wherein the subtractive manufacturing technique includes one or more of milling, core-drilling, and sawing to define at least one of the upper wall rib portion of the upper wall and the lower wall rib portion of the lower wall of the weldment.

21. A chamber body for a chamber arrangement of a semiconductor processing system made using the method of claim 14.

22. A material layer deposition method, comprising:
at a chamber body including a ceramic weldment having a lower wall, a sidewall coupled to the lower wall by a sidewall-to-lower wall weld, and an upper wall coupled to the sidewall by a sidewall-to-upper wall weld, the upper wall having an upper wall plate portion and an upper wall rib portion extending therefrom formed from a singular quartz workpiece using a subtractive manufacturing technique, the upper wall further having a unwelded ribbed region overlying the lower wall,
seating a substrate within the chamber body;
heating the substrate using an upper heater element array;
exposing the substrate to a silicon-containing material precursor;
depositing a silicon-containing material layer onto the substrate using the silicon-containing material precursor;
throttling heating of the substrate using the upper heater element array during deposition of the silicon-containing material layer using a pyrometer;
wherein the upper heater is optically coupled to the substrate by the unwelded ribbed region of the upper wall;
wherein the pyrometer is optically coupled to the substrate by the unwelded ribbed region of the upper wall; and
whereby unwelded ribbed region of the upper wall limits cross-substrate variation within the material relative to a chamber body having an upper wall welded ribbed region optically coupling an upper heater element array and/or a pyrometer to the substrate.
